(19) United States
(12) Patent Application Publication
(10) Pub. No.: US 2025/0372554 A1
(43) Pub. Date: Dec. 4, 2025

(54) PAD-LESS HYBRID BONDING

(71) Applicant: ADEIA SEMICONDUCTOR BONDING TECHNOLOGIES INC., San Jose, CA (US)

(72) Inventors: Rajesh KATKAR, Milpitas, CA (US); Gaius Gillman FOUNTAIN, JR., Youngsville, NC (US); Belgacem HABA, Saratoga, CA (US); Cyprian Emeka UZOH, San Jose, CA (US); Laura Wills MIRKARIMI, Sunol, CA (US)

(21) Appl. No.: 18/745,764

(22) Filed: Jun. 17, 2024

Related U.S. Application Data
(60) Provisional application No. 63/652,861, filed on May 29, 2024.

(51) Int. Cl. H01L 23/00

(52) U.S. Cl. CPC H01L 24/08; H01L 24/80; H01L 24/03; H01L 24/05; H01L 2224/03622; H01L 2224/05552; H01L 2224/05557; H01L 2224/08145; H01L 2224/80009; H01L 2224/80031; H01L 2224/80047; H01L 2224/80895; H01L 2224/80896

(57) ABSTRACT

Disclosed herein are methods of forming a microelectronic component. In some embodiments, the methods include providing an element having a metallization layer having a plurality of metal lines extending in a lateral direction along a surface of the metallization layer. The method further includes forming a dielectric layer over the metallization layer, preparing the element for direct bonding, and exposing a portion of at least one of the plurality of metal lines to define an exposed portion. The exposed portion and the dielectric layer form part of a hybrid bonding surface.

### INCORPORATION BY REFERENCE TO ANY PRIORITY APPLICATIONS

Any and all applications for which a foreign or domestic priority claim is made are identified in the Application Data Sheet as filed with the present application are hereby incorporated by reference under 37 CFR 157.

This application claims the benefit under 35 U.S.C. § 119(e) to U.S. Provisional Application No. 63/652,861, entitled “PAD-LESS HYBRID BONDING,” filed May 29, 2024, the entirety of which is hereby incorporated by reference herein.

### BACKGROUND

### Field

This application relates to direct bonding methods and structures, and more particularly to hybrid bonding methods and structures.

### Description of the Related Art

Microelectronic elements, such as integrated device dies or chips, may be mounted or stacked on other elements thereby forming a bonded structure. Direct bonding can be conducted at low temperatures and without external pressure. For example, hybrid bonding involves directly bonding non-conductive features (e.g., inorganic dielectrics) of different elements together, without intervening adhesives, while also directly bonding conductive features (e.g., metal pads) of the elements together. For example, a microelectronic element can be mounted to a carrier, such as a wafer, an interposer, a reconstituted wafer or other element, etc. As another example, a microelectronic element can be stacked on top of another microelectronic element, e.g., a first integrated device die can be stacked on a second integrated device die. Each of the microelectronic elements can have conductive pads for mechanically and electrically bonding the elements to one another. These conductive pads are typically formed as part of a direct bonding layer formed on the surface of a metallization layer of the microelectronic elements. However, forming the separate bonding layers requires additional processing steps that increase the cost of forming the bonded microelectronic elements and there is a continuing need for improved methods for forming bonded structures at lower costs.

### BRIEF DESCRIPTION OF THE DRAWINGS

FIG. 1A is a schematic side sectional view of two elements before being directly bonded, according to an embodiment.

FIG. 1B is a schematic side sectional view of the two elements of FIG. 1A after being directly bonded, according to an embodiment.

FIG. 2A is a plan view of an element having a metallization layer according to some embodiments.

FIG. 2B is a plan view of the element of FIG. 2A having a dielectric layer formed over a surface of the metallization layer.

FIG. 2C is a cross-sectional view of the element taken along lines A-A of FIG. 2B, according to a first embodiment.

FIG. 2D is a cross-sectional view of the element taken along lines A-A of FIG. 2B, according to a second embodiment.

FIG. 3 is a flowchart illustrating a process of forming a bonded structure that includes hybrid bonded elements, according to the first embodiment.

FIGS. 4A-4E are schematic side sectional views of microelectronic elements at various blocks of a process like that of FIG. 3.

FIG. 5 is a flowchart illustrating a process of forming a bonded structure that includes hybrid bonded elements, according to the second embodiment.

FIGS. 6A-6G are schematic side sectional view of microelectronic elements at various blocks of a process like that of FIG. 5.

FIG. 7 is a flowchart illustrating a process forming an element having a metallization layer and that is prepared for hybrid bonding, according to some embodiments.

FIGS. 8A-8D are schematic side sectional views of bonded structures having a first element hybrid bonded to a second element, where at least the first element has is generally similar to any of the elements shown and described in connection with FIGS. 2B-2D, 4A-4E, and 6A-6F, according to some embodiments.

FIG. 9 is a schematic side sectional view of a first element and a second element that is configured to be hybrid bonded to the first element, where the second element includes a protruding bond pad, according to some embodiments.

FIG. 10 is a schematic side sectional view of a bonded structure that includes first and second elements hybrid bonded together and having a metal interconnection formed from multiple small openings, according to some embodiments.

FIG. 11A is a plan view of an element having a metallization layer that includes extension portions and cut-out portions, according to some embodiments.

FIG. 11B is a plan view of the element of FIG. 11A having a patterned dielectric layer formed over a surface of the metallization layer.

### DETAILED DESCRIPTION OF THE PREFERRED EMBODIMENT

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element, such as direct bonding a dielectric material and a metal material on one element to corresponding dielectric and metal materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

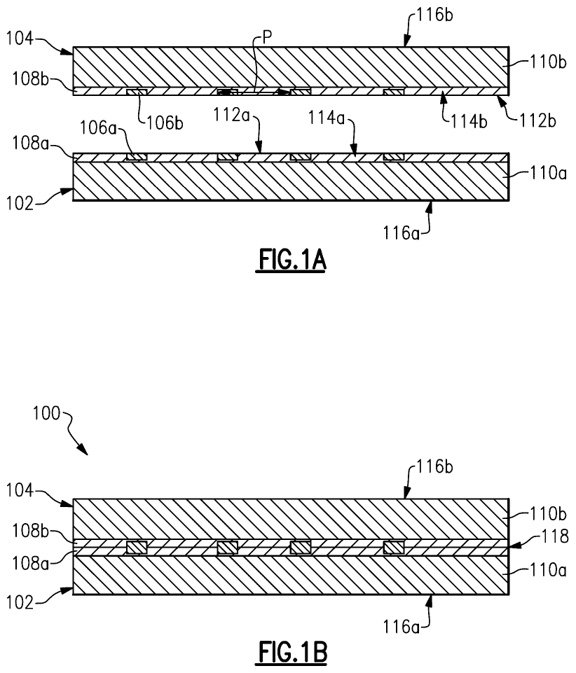

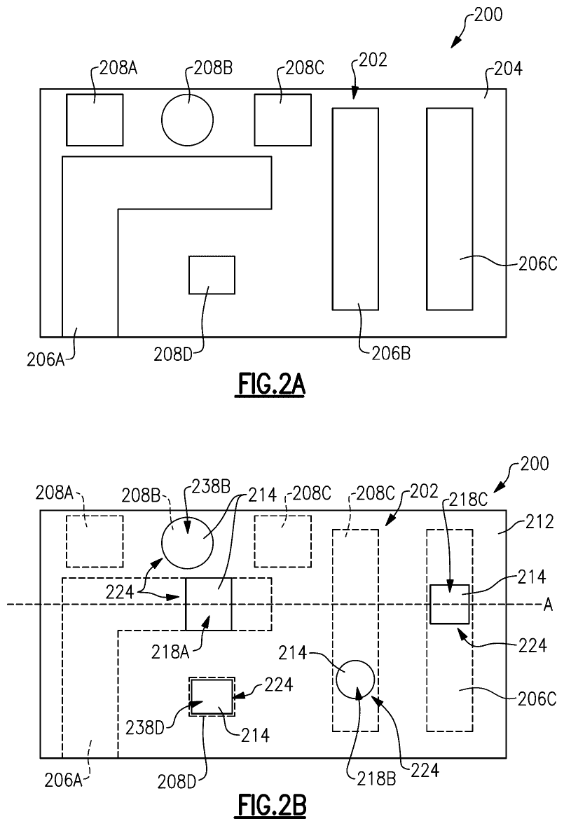

With reference to FIGS. 1A and 1B, in various embodiments, bonding layers 108a and/or 108b can comprise a non-conductive material such as a dielectric material or an undoped semiconductor material, such as undoped silicon, which may include native oxide. Suitable dielectric bonding surfaces or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials. In some embodiments, the dielectric materials comprise cured polymers.

In other embodiments, the bonding layers can comprise an electrically conductive material, such as a deposited conductive oxide material, e.g., indium tin oxide (ITO), as disclosed in U.S. patent application Ser. No. 18/391,173, filed Dec. 20, 2023, the entire content of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), or partially cured polymer, which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 1A and 1B schematically illustrate cross-sectional side views of first and second elements 102, 104 prior to and after, respectively, a process for forming a directly bonded structure, and more particularly a hybrid bonded structure, according to some embodiments. In FIG. 1B, a bonded structure 100 comprises the first and second elements 102 and 104 that are directly bonded to one another at a bond interface 118 without an intervening adhesive. Conductive features 106a of a first element 102 may be electrically connected to corresponding conductive features 106b of a second element 104. In the illustrated hybrid bonded structure 100, the conductive features 106a are directly bonded to the corresponding conductive features 106b without intervening solder or conductive adhesive.

The conductive features 106a and 106b of the illustrated embodiment are embedded in, and can be considered part of, a first bonding layer 108a of the first element 102 and a second bonding layer 108b of the second element 104, respectively. Field regions of the bonding layers 108a, 108b extend between and partially or fully surround the conductive features 106a, 106b. The bonding layers 108a, 108b can comprise layers of non-conductive materials suitable for direct bonding, as described above, and the field regions are directly bonded to one another without an adhesive. The non-conductive bonding layers 108a, 108b can be disposed on respective front sides 114a, 114b of base substrate portions 110a, 110b.

The first and second elements 102, 104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 102, 104, and back-end-of-line (BEOL) interconnect layers over such semiconductor portions. The bonding layers 108a, 108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 110a, 110b, and can electrically communicate with at least some of the conductive features 106a, 106b. Active devices and/or circuitry can be disposed at or near the front sides 114a, 114b of the base substrate portions 110a, 110b, and/or at or near opposite backsides 116a, 116b of the base substrate portions 110a, 110b. In other embodiments, the base substrate portions 110a, 110b may not include active circuitry, but may instead comprise dummy substrates, passive interposers, passive optical elements (e.g., glass substrates, gratings, lenses), etc. The bonding layers 108a, 108b are shown as being provided on the front sides of the elements, but similar bonding layers can be additionally or alternatively provided on the back sides of the elements.

In some embodiments, the base substrate portions 110a, 110b can have significantly different coefficients of thermal expansion (CTEs), and bonding elements that include such different based substrate portions can form a heterogenous bonded structure. The CTE difference between the base substrate portions 110a and 110b, and particularly between bulk semiconductor (typically single crystal) portions of the base substrate portions 110a, 110b, can be greater than 5 ppm/° C. or greater than 10 ppm/° C. For example, the CTE difference between the base substrate portions 110a and 110b can be in a range of 5 ppm/° C. to 100 ppm/° C., 5 ppm/° C. to 80 ppm/° C., 10 ppm/° C. to 100 ppm/° C., or 10 ppm/° C. to 40 ppm/° C.

In some embodiments, one of the base substrate portions 110a, 110b can comprise optoelectronic single crystal materials, including perovskite materials, that are useful for optical piezoelectric or pyroelectric applications, and the other of the base substrate portions 110a, 110b comprises a more conventional substrate material. For example, one of the base substrate portions 110a, 110b comprises lithium tantalate (LiTaO₃) or lithium niobate (LiNbO₃), and the other one of the base substrate portions 110a, 110b comprises silicon (Si), quartz, fused silica glass, sapphire, or a glass. In other embodiments, one of the base substrate portions 110a, 110b comprises a III-V single semiconductor material, such as gallium arsenide (GaAs) or gallium nitride (GaN), and the other one of the base substrate portions 110a, 110b can comprise a non-III-V semiconductor material, such as silicon (Si), or can comprise other materials with similar CTE, such as quartz, fused silica glass, sapphire, or a glass. In still other embodiments, one of the base substrate portions 110a, 110b comprises a semiconductor material and the other of the base substrate portions 110a, 110b comprises a packaging material, such as a glass, quartz, organic or ceramic substrate.

In some arrangements, the first element 102 can comprise a singulated element, such as a singulated integrated device die. In other arrangements, the first element 102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 104 can comprise a singulated element, such as a singulated integrated device die. In other arrangements, the second element 104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 102, 104 are shown, any suitable number of elements can be stacked in the bonded structure 100. For example, a third element (not shown) can be stacked on the second element 104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 108a, 108b, the bonding layers 108a, 108b can be prepared for direct bonding. Non-conductive bonding surfaces 112a, 112b at the upper or exterior surfaces of the bonding layers 108a, 108b can be prepared for direct bonding by polishing, for example, by chemical mechanical polishing (CMP). The roughness of the polished bonding surfaces 112a, 112b can be less than 30 Å rms. For example, the roughness of the bonding surfaces 112a and 112b can be in a range of about 0.1 Å rms to 15 Å rms, 0.5 Å rms to 10 Å rms, or 1 Å rms to 5 Å rms. Polishing can also be tuned to leave the conductive features 106a, 106b recessed relative to the field regions of the bonding layers 108a, 108b.

Preparation for direct bonding can also include cleaning and exposing one or both of the bonding surfaces 112a, 112b to a plasma and/or etchants to activate at least one of the surfaces 112a, 112b. In some embodiments, one or both of the surfaces 112a, 112b can be terminated with a species after activation or during activation (e.g., during the plasma and/or etch processes). Without being limited by theory, in some embodiments, the activation process can be performed to break chemical bonds at the bonding surface(s) 112a, 112b, and the termination process can provide additional chemical species at the bonding surface(s) 112a, 112b that alters the chemical bond and/or improves the bonding energy during direct bonding. In some embodiments, the activation and termination are provided in the same step, e.g., a plasma to activate and terminate the surface(s) 112a, 112b. In other embodiments, one or both of the bonding surfaces 112a, 112b can be terminated in a separate treatment to provide the additional species for direct bonding. In various embodiments, the terminating species can comprise nitrogen. For example, in some embodiments, the bonding surface(s) 112a, 112b can be exposed to a nitrogen-containing plasma. Other terminating species can be suitable for improving bonding energy, depending upon the materials of the bonding surfaces 112a, 112b. Further, in some embodiments, the bonding surface(s) 112a, 112b can be exposed to fluorine. For example, there may be one or multiple fluorine concentration peaks at or near a bond interface 118 between the first and second elements 102, 104. Typically, fluorine concentration peaks occur at interfaces between material layers. Additional examples of activation and/or termination treatments may be found in U.S. Pat. Nos. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 100, the bond interface 118 between two non-conductive materials (e.g., the bonding layers 108a, 108b) can comprise a very smooth interface with higher nitrogen (or other terminating species) content and/or fluorine concentration peaks at the bond interface 118. In some embodiments, the nitrogen and/or fluorine concentration peaks may be detected using various types of inspection techniques, such as SIMS techniques. The polished bonding surfaces 112a and 112b can be slightly rougher (e.g., about 1 Å rms to 30 Årms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 108a and 108b can be directly bonded to one another without an adhesive. In some embodiments, the elements 102, 104 are brought together at room temperature, without the need for application of a voltage, and without the need for application of external pressure or force beyond that used to initiate contact between the two elements 102, 104. Contact alone can cause direct bonding between the non-conductive surfaces of the bonding layers 108a, 108b (e.g., covalent dielectric bonding). Subsequent annealing of the bonded structure 100 can cause the conductive features 106a, 106b to directly bond.

In some embodiments, prior to direct bonding, the conductive features 106a, 106b are recessed relative to the surrounding field regions, such that a total gap between opposing contacts after dielectric bonding and prior to anneal is less than 15 nm, or less than 10 nm. Because the recess depths for the conductive features 106a and 106b can vary across each element, due to process variation, the noted gap can represent a maximum or an average gap between corresponding conductive features 106a, 106b of two joined elements (prior to anneal). Upon annealing, the conductive features 106a and 106b can expand and contact one another to form a metal-to-metal direct bond.

During annealing, the conductive features 106a, 106b (e.g., metallic material) can expand while the direct bonds between surrounding non-conductive materials of the bonding layers 108a, 108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 106a, 106b can comprise discrete pads, contacts, electrodes, or traces at least partially embedded in the non-conductive field regions of the bonding layers 108a, 108b. In some embodiments, the conductive features 106a, 106b can comprise exposed contact surfaces of TSVs (e.g., through silicon vias).

As noted above, in some embodiments, in the elements 102, 104 of FIG. 1A prior to direct bonding, portions of the respective conductive features 106a and 106b can be recessed below the non-conductive bonding surfaces 112a and 112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 106a, 106b or to average depths of the recesses relative to local non-conductive field regions. Even for an individual conductive feature 106a, 106b, the vertical recess can vary across the feature, and so can be measured at or near the lateral middle or center of the cavity in which a given conductive feature 106a, 106b is formed, or can be measured at the sides of the cavity.

Beneficially, the use of hybrid bonding techniques (such as Direct Bond Interconnect, or DBIR, techniques commercially available from Adeia of San Jose, CA) can enable high density of connections between conductive features 106a, 106b across the direct bond interface 118 (e.g., small or fine pitches for regular arrays).

In some embodiments, a pitch P of the conductive features 106a, 106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 106a and 106b to one of the lateral dimensions (e.g., a diameter) of the bonding pad is less than is less than 20, or less than 10, or less than 5, or less than 3 and sometimes desirably less than 2. In various embodiments, the conductive features 106a and 106b and/or traces can comprise copper or copper alloys, although other metals may be suitable, such as nickel, aluminum, or alloys thereof. The conductive features disclosed herein, such as the conductive features 106a and 106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 102, 104, as shown, the orientations of one or more conductive features 106a, 106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 106b in the bonding layer 108b (and/or at least one internal conductive feature, such as a BEOL feature) of the upper element 104 may be tapered or narrowed upwardly, away from the bonding surface 112b. By way of contrast, at least one conductive feature 106a in the bonding layer 108a (and/or at least one internal conductive feature, such as a BEOL feature) of the lower element 102 may be tapered or narrowed downwardly, away from the bonding surface 112a. Similarly, any bonding layers (not shown) on the backsides 116a, 116b of the elements 102, 104 may taper or narrow away from the backsides, with an opposite taper orientation relative to front side conductive features 106a, 106b of the same element.

As described above, in an anneal phase of hybrid bonding, the conductive features 106a, 106b can expand and contact one another to form a metal-to-metal direct bond. In some embodiments, the materials of the conductive features 106a, 106b of opposite elements 102, 104 can interdiffuse during the annealing process. In some embodiments, metal grains grow into each other across the bond interface 118. In some embodiments, the metal is or includes copper, which can have grains oriented along the 111 crystal plane for improved copper diffusion across the bond interface 118. In some embodiments, the conductive features 106a and 106b may include nanotwinned copper grain structure, which can aid in merging the conductive features during anneal. There is substantially no gap between the non-conductive bonding layers 108a and 108b at or near the bonded conductive features 106a and 106b. In some embodiments, a barrier layer may be provided under and/or laterally surrounding the conductive features 106a and 106b (e.g., which may include copper). In other embodiments, however, there may be no barrier layer under the conductive features 106a and 106b.

As previously described, in some embodiments, the bonding layers 108a, 108b can be formed as distinct bonding layers on the base substrate portions 110a, 110b. The base substrate portions 110a, 110b can include metallization layers (e.g., BEOL layers, RDLs, etc.) having metal features (e.g., metal lines) and, in these embodiments, the bonding layers 108a, 108b are formed over the metallization layers such that the conductive features 106a, 106b of the bonding layers 108a, 108b are separately formed and electrically connected to the metal lines in the metallization layers. However, forming distinct bonding layers over the elements 102, 104 that include deposited metal entails additional processing steps, including depositing a dielectric layer over the metallization layer, patterning the dielectric layer, depositing metal over the patterned dielectric layer, and then planarizing and polishing the bonding layer. These additional processing steps increase the cost, time, and complexity needed to produce the elements.

Moreover, polishing the bonding layer, including embedded metal, in a way that produces a uniform height of the metal relative to the dielectric field regions across the substrate can be challenging, particularly with non-uniform pad patterns that produce loading effects across a substrate, uneven dishing of the embedded metal, and/or uneven recesses in the metal pads. For this reason, hybrid bonding layers typically strive to present uniform patterns across the substrate, resulting in thousands of unnecessary or redundant metal pads that are unconnected to circuits and therefore serve as dummy pads, because the circuits simply do not require such numbers of connections. Such dummy pads can represent greater than 10% of the conductive features exposed at the element's bonding surface, and can sometimes even represent greater than 90% of the conductive features exposed at the element's bonding surface, which can be wasteful. Some stacked devices or applications may need a minimum pitch of about 1 μm between adjacent interconnections/pads, which typically results in an interconnect/pad density of about 1 million interconnections/mm². For example, for a hypothetical die size of 20 mm×20 mm, the total number of pads and interconnects at a given bonding surface would be about 0.4 billion. However, in this hypothetical example, only a few thousand (or 10s of thousands or 100 s of thousands) interconnections in total may actually be used to facilitate communication between the stacked dies, which means that greater than 99% of the pads and/or interconnects at the bonding surfaces can be redundant.

To address these challenges, an element can be formed that allows for hybrid bonding to the element without having to form a distinct metallization layer for hybrid bonding.

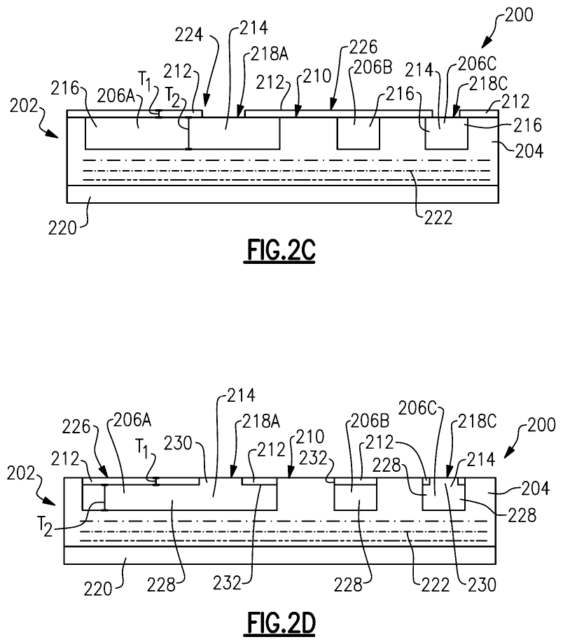

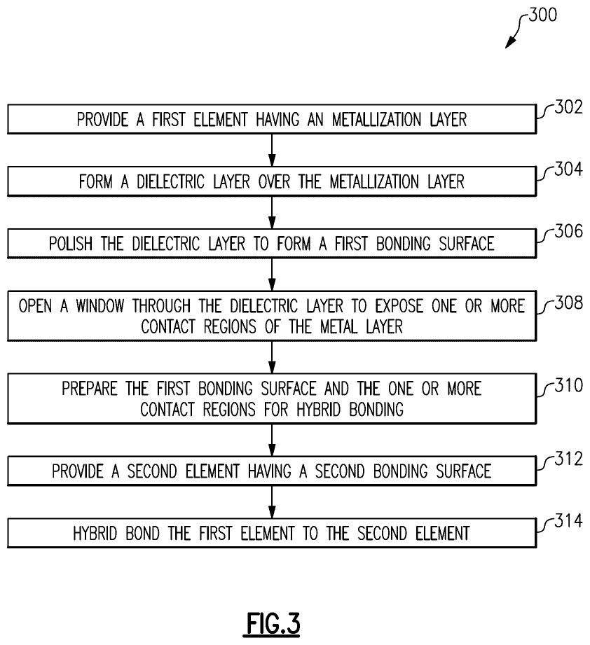

FIG. 2A illustrates a top-down plan view of a portion of an element 200. The element 200 comprises a base substrate portion (not shown) and a metallization layer 202 formed over the base substrate portion. The metallization layer 202 includes a field dielectric 204, metal lines 206A-206C, and pads 208, which can include test pads 208A and 208C and operational pads 208B and 208D, where the metal lines 206A-206C and pads 208A-208D are embedded in the field dielectric 204. In some embodiments, the operational pads 208B, 208D can be a part of a via that extends at least partially through the metallization layer 202. The metal lines 206A-206C can extend in a lateral direction along a surface 210 of the metallization layer 202. The metal lines 206A-206C, the test pads 208A, 208C, and the operational pads 208B, 208-D can be electrically connected to active devices and/or circuitry within the base substrate portion of the element 200. The metal lines 206A-206C are configured to facilitate communication between active devices/circuitry within the element 200 and/or between active devices/circuitry within the element 200 and other elements that are to be bonded to the element 200. In the illustrated embodiment, the metal line 206A has a bend while metal lines 206B and 206C are straight. In other embodiments, however, each of the metal lines 206A- 206C can be straight, can have one or more bends, or can be curved. In some embodiments, one or more of the metal lines 206A-206C can have one or more cut outs or extensions to accommodate the layout/structure of another element bonded to the element 200. In the illustrated embodiment, each of the metal lines 206A-206C have approximately the same width and depth. In other embodiments, one or more of the metal lines 206A-206C can have a different width or depth. In general, each of the metal lines 206A-206C can have any suitable size and shape.

In some embodiments, the element 200 comprises a wafer having a plurality of device regions, where each of the device regions comprises metal lines, pads, and a field dielectric that surrounds the metal lines and pads. In these embodiments, after forming the element 200, the device regions in the element 200 can be tested to determine whether the individual device regions are performing properly. The pads 208A-208D are also connected to active devices and/or circuitry within the base substrate portion of the element 200 and test pads 208A, 208C can be probed (e.g., using an external probe that physically contacts the test pads 208A, 208C) to facilitate this testing. If the testing shows that a given device region is preforming properly, the system can identify that device region as a known good die (KGD). The pads 208A-208D can be rectangular (e.g., square), rounded (e.g., circular, elliptical), hexagonal, or any other suitable regular or irregular shape. In some embodiments, the pads 208A-208D can all be the same size. In other embodiments, one or more of the pads 208A-208D can be a different size. In general, each of the pads can have any suitable size and shape.

In some embodiments, the field dielectric 204 comprises an inorganic dielectric, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. In some embodiments, the metal lines 206A-206C and the pads 208 comprise a conductive metal, such as copper, aluminum, nickel, gold, platinum, palladium, tin, or tungsten. In some embodiments, the metal lines 206A-206C and the pads 208 comprise two or more conductive metals. For example, in some embodiments, the metal lines 206A-206C and the pads 208 comprise an alloy that includes two or more conductive metals mixed together. In other elements, the metal lines 206A-206C and the pads 208 comprise a conductive layer formed on a based layer, where the conductive layer includes one or more conductive metals (e.g., copper, aluminum, nickel, gold, platinum, palladium, tin, tungsten), and the base metal includes a different conductive metal. In some embodiments, the metallization layer 202 is formed at a back side of the element 200. In other embodiments, the metallization layer 202 is formed at a front side of the element 200. The illustrated metallization layer 202 can be the uppermost or last metallization layer of a plurality of BEOL metallization layers on a particular side of a microelectronic element. Accordingly, the metallization layer 202 can be formed at a chip foundry, for example, using process nodes typical for BEOL at the foundry, as opposed to a packaging facility.

In hybrid bonding, non-conductive features of a first element directly contact and are directly bonded to non-conductive features of a second element while conductive features of the first element directly contact and are directly bonded to conductive features of the second element. However, care must be taken to ensure that, during the hybrid bonding processes, the conductive features on the first element are aligned with corresponding conductive features on the second element to ensure that the bond strength between the elements is sufficiently high. Additionally, if a conductive feature on the first element is misaligned with the corresponding conductive feature on the second element, the conductive feature on the first element can electrically connect to a different conductive feature on the second element, which can result in undesirable crosstalk and substrate coupling between the first and second elements.

In the embodiment shown in FIG. 2A, the pads 208A, 208C can be test pads that are used during testing and validation of the element 200 but are otherwise not used during normal operation of the element 200. Accordingly, if the element 200 were to be bonded to another element without covering the test pads 208A, 208C, the test pads could undesirably electrically connect to a conductive feature on the other element, which could allow for electrical communications to be transmitted between the elements via the test pads, which could negatively affect the operation of the bonded structure. Additionally, the metal lines 206A-206C, which can be configured to facilitate communication between active device circuitry within the element 200 and active devices/circuitry on another element that is bonded to the element 200, extend across the surface 210 of the element 200 and the conductive metal that forms the metal lines 206A-206C is exposed along the length of the metal lines 206A-206C. If the element 200 were to be bonded to another element without covering most of the metal lines 206 (i.e., without covering all of the metal lines 206 except for the portions of the metal lines 206 that are intended to electrically connect to a conductive feature on the other element), then each of the metal lines could overlap with and electrically connect to multiple conductive features on the other element, which could negatively affect the operation of the bonded structure.

To prevent the undesirable crosstalk and substrate coupling between the element 200 and another element hybrid bonded to the element 200, a dielectric layer can be formed over the metallization layer 202 that covers the test pads 208A, 208C and partially covers the metal lines 206A-206C. In some embodiments, the dielectric layer can also partially cover one or both of the operational pads 208B, 208D. FIG. 2B illustrates a top-down plan view of the element 200 having a dielectric layer 212 formed over the metallization layer 202. The dielectric layer 212 partially covers the metal lines 206A-206C without covering exposed portions 214 of the metal lines 206A-206C. The dielectric layer 212 has windows 224 formed therein that are positioned over the metal lines 206A-206C to expose the exposed portions 214 of the metal lines 206A-206C. With this arrangement, the dielectric layer prevents covered portions 216 (FIG. 2C) of the metal lines 206A-206C from contacting and electrically connecting to conductive features on another element that is hybrid bonded to the element 200 while still allowing for the exposed portions 214 to directly bond and electrically connect to the conductive features on the other element. The dielectric layer 212 fully covers the test pads 208A, 208C but may not cover or only partially cover the operational pads 208B, 208D. In the illustrated embodiment, the windows 224 are formed over the operational pads 208B, 208D such that the covered portions 216 of the operational pad 208D is covered by the dielectric layer 212 while the exposed portion 214 of the operational pads 208B, 208D are not covered by the dielectric layer 212. With this arrangement, the dielectric layer prevents the test pads 208A, 208C and the covered portions 216 of the operational pad 208D from contacting and electrically connecting to conductive features on another element that is hybrid bonded to the element 200 while still allowing the exposed portions 214 of the operational pads 208B, 208D to contact and electrically connect to corresponding features on the other element.

In some embodiments the dielectric layer 212 comprises an inorganic dielectric, such as silicon oxide or a nitrogen-containing dielectric material. For example, in some embodiments, the dielectric layer 212 comprises silicon nitride, silicon carbonitride, silicon oxycarbonitride, silicon oxynitride, or a combination thereof. In some embodiments, the dielectric layer 212 comprises a different material from the material of the field dielectric 204. In some embodiments, the dielectric layer 212 comprises multiple dielectric materials. For example, in some embodiments, the dielectric layer 212 comprises a first layer that includes silicon oxide and a second layer that includes a nitrogen-containing dielectric material.

The exposed portions 214 of the metal lines 206A-206C define contact regions 218A-218C of the metallization layer 202 that are configured to facilitate communications between active circuitry within the element 200 and active circuitry in another element that is hybrid bonded to the element 200. Similarly, the exposed portions 214 of the operational pads 208B, 208D define contact region 238B, 238D. When the element 200 is hybrid bonded to another element, the contact regions 218A-218C, 238B, 238D are configured to directly contact and form metal-to-metal direct bonds with contact regions on the other element.

In the illustrated embodiment, the contact regions 218A, 218C, and 218D are square while the contact regions 218B and 238B are circular. In other embodiments, each of the contact regions 218A-218C, 238B, 238D can be rectangular, rounded, hexagonal, or any other suitable regular or irregular shape. In some embodiments, each of the contact regions 218A-218C, 238B, 238D have the same shape. In other embodiments, however, one or more of the contact regions 218A-218C, 238B, 238D have a different shape. In the illustrated embodiment, the contact region 218A has a width that is approximately the same as the width of the metal line 206A while contact regions 218B and 218C have widths that are less than the widths of the metal lines 206B and 206C and that are less than the width of the contact region 218A. Similarly, in the illustrated embodiment, the contact region 238B has a width that is approximately the same as the width of the operational pad 208B while the contact region 238D has a width that is less than the width of the contact operational pad 208D and that is less than the width of the contact region 238B. In some embodiments, each of the contact regions 218A-218C can have a width that is approximately the same as the width as the corresponding metal line 206A-206C and each of the contact regions 238B, 238D can have a width that is approximately the same as the width of the corresponding operational pad 208B, 208D. In other embodiments, one or more of the contact regions 218A-218C can have a width that is different than (e.g., less than) the width of the corresponding metal line 206A-206C and one or more of the contact regions 238B, 238D can have a width that is different than (e.g., less than) the width of the corresponding operational pad 208B, 208D. Relatedly, in some embodiments, each of the contact regions 218A-218C, 238B, 238D can have the same width. In other embodiments, one or more of the contact regions 218A-218C, 238B, 238D can have a different width. In general, each of the contact regions 218A-218C, 238B, 238D can have any suitable size and shape. Additionally, the size and shape of the contact regions 218A-218C, 238B, 238D can depend on the size and shape of the corresponding windows 224 formed in the dielectric layer 212. As previously discussed, in some embodiments, one or more of the metal lines 206 can have cut-outs or extensions to accommodate the layout/structure of another element bonded to the element 200. In these embodiments, the contact region 218 of that metal line 206 can be formed on the extension.

In the illustrated embodiment, the element 200 does not include any dummy pads formed at the bonding surface 226. In other embodiments, however, the metallization layer 212 can include one or more dummy pads exposed at the bonding surface 226. For example, in some embodiments, the pad 208D is not an operational pad but is instead a dummy pad that is not electrically connected to any buried metal lines or TSVs but that is exposed at the bonding surface to participate in hybrid bonding between the element 200. Covering the test pads 208A, 208C reduces the number of dummy pads needed to form a uniform pattern on the bonding surface 226 of the element 200. This is because covering the test pads 208A, 208C reduces the number of exposed metal pads at the bonding surface, which can increase the uniformity of the pad pattern and can therefore reduce the loading effects, uneven dishing of the embedded metal, and/or uneven recesses in the individual metal pads. Accordingly, in some embodiments, the element 200 can have some dummy pads but the relative amount of dummy pads present at the bonding surface 226 can be reduced. For example, in some embodiments, dummy pads represent less than 50% of the conductive features (e.g., contact regions 218A-218C, 238B, 238D) exposed at the bonding surface 226 of the element 200. In other embodiments, dummy pads represent less than 40%, less than 30%, less than 25%, less than 20%, less than 15%, less than 10%, less than 5%, less than 2%, or less than 1% of the conductive features exposed at the bonding surface 226.

FIG. 2C is a cross-sectional view of an embodiment of the element 200 taken along lines A-A of FIG. 2B. The element 200 includes base substrate portion 220, the metallization layer 202 formed over the base substrate portion 220, and the dielectric layer 212 formed over the metallization layer 202. The base substrate portion 220 includes active devices and/or circuitry and the metal lines 206A-206C can be electrically connected to the active devices/circuitry (e.g., via buried metal lines 222 of metallization levels below the metallization layer 202). In the illustrated embodiment, the dielectric layer 212 is formed over the surface 210 of the element 200 such that the dielectric layer 212 completely covers the field dielectric 204 and the covered portions 216 of the metallization layer 202. However, the windows 224 are formed in the dielectric layer 212 such that the dielectric layer 212 does not cover the exposed portions 214 of the metal lines 206A-206C.

As shown in FIG. 2B, the contact regions 218A and 218C (which are formed from the exposed portions 214 of the metal lines 206A and 206C and the windows 224 formed over the metal lines 206A and 206C) are aligned with the lines A-A while the contact regions 218B (which is formed from the exposed portion 214 of the metal line 206B and the window 224 formed over the metal line 206B), 238B (which is formed from the exposed portion 214 of the operational pad 208B), and 238D (which is formed from the exposed portion 214 of the operational pad 208D) are not aligned with the lines A-A. Accordingly, in the cross-sectional view illustrated in FIG. 2C, the contact regions 208A and 208C are shown while the contact regions 218B, 238B, 238D are not. With this arrangement, the dielectric layer 212 and the contact regions 218A-218C, 238B, 238D can form a bonding surface 226 of the element 200, where the bonding surface 226 does not include the underlying field dielectric 204. Accordingly, when the element illustrated in FIG. 2C is hybrid bonded to another element, the dielectric layer 212 can contact and directly bond to a corresponding non-conductive feature of the other element and the contact regions 218A-218C, 238B, 238D can contact and directly bond to corresponding conductive features of the other element while the field dielectric 204 does not contact or otherwise participate in direct bonding with the other element.

As shown in FIG. 2B, the width of the contact region 218C is less than the width of the metal line 206C. Accordingly, the window 224 over the metal line 206C is formed in the dielectric layer 212 such that the dielectric layer 212 overlaps with the portions of the metal line 206C that are immediately adjacent to the exposed portion 214 that forms the contact region 218C. With this arrangement, the size and shape of the window 224 formed over a given metal line 206A-206C, or operational pad 208B, 208D can be used to adjust the size and shape of the corresponding contact region 218A-218C, 238B, 238D.

In the illustrated embodiments, the windows 224 are formed in the dielectric layer 212 such that the windows 224 are positioned directly over the metal lines 206A-206C and operational pads 208B, 208D without being positioned over the underlying field dielectric layer 204. With this arrangement, the metal lines 206A-206C and the operational pads 208B, 208D are exposed through the windows 224 and no part of the underlying field dielectric layer 204 is exposed through the windows 224. In other embodiments, however, the windows 224 can be formed in the dielectric layer 212 such that one or more of the windows 224 is offset from the underlying metal lines 206A-206C and operational pads 208B, 208D. In these embodiments, a portion of the field dielectric layer 204 can also be exposed through the windows 224.

The dielectric layer 212 can have a thickness T₁ that is less than a thickness T₂ of the portion of the metal lines 206A-206C over which the dielectric layer 212 is formed. For example, in some embodiments, the T₁ can be between 0.05% and 50% of T₂. In other embodiments, however, the thickness T₁ can be a different size relative to T₂. For example, in some embodiments, between 20% and 50% of T₂, between 0.05% and 1% of T₂, between 0.05% and 20% of T₂, between 10% and 20% of T₂, between 0.5% and 10% of T₂, between 5% and 10% of T₂, between 1% and 5% of T₂, between 0.5% and 1% of T₂, less than 40% of T₂, less than 30% of T₂, less than 20% of T₂, less than 10% of T₂, less than 5% of T₂, than 2% of T₂, or less than 1% of T₂. In some embodiments, the thickness T₁ is between 2 nm and 100 nm, between 2 nm and 80 nm, between 2 nm and 50 nm, between 2 nm and 40 nm, between 2 nm and 20 nm, between 2 nm and 10 nm, between 5 nm and 10 nm, between 2 nm and 5 nm, less than 40 num, less than 20 nm, less than 10 nm, less than 5 nm, or a value in a range defined by any of these values, and thickness T2 is between 0.1 μm and 5 μm, between 0.5 μm and 5 μm, between 0.1 μm and 1 μm, between 1 μm and 5 μm, between 0.5 and 1 μm, greater than 5 μm, greater than 2 μm, greater than 1 μm, greater than 0.5 μm, or a value in a range defined by any of these values.

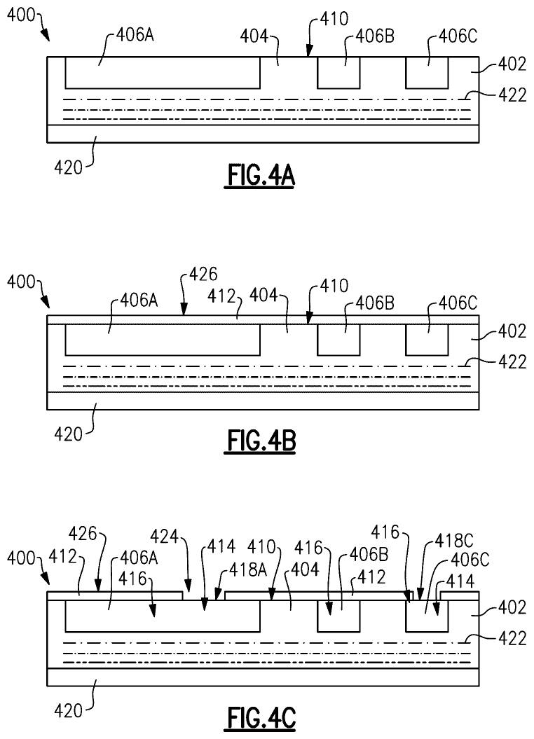

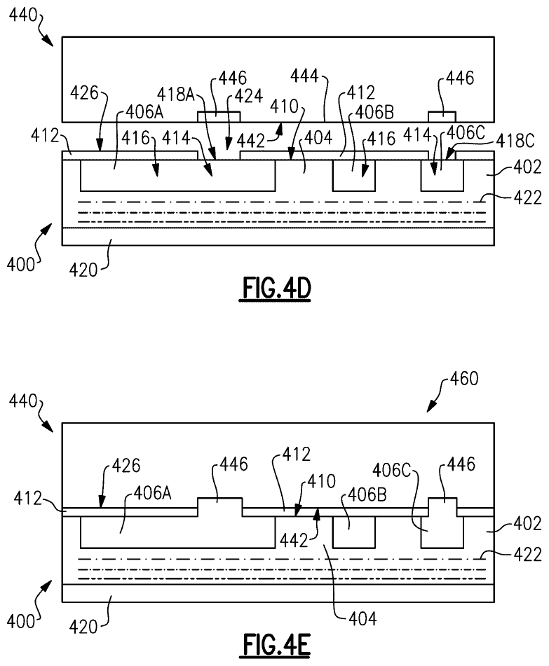

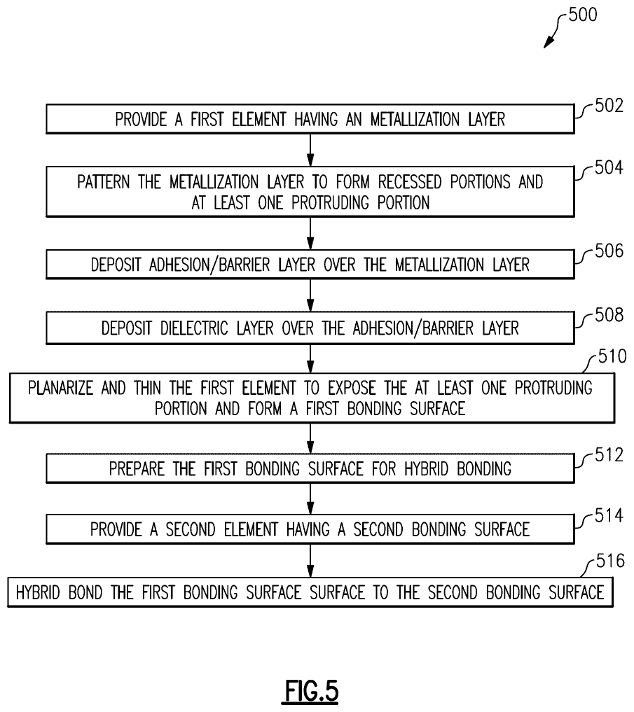

The thickness of the dielectric layer 212 defines the recess of contact regions 218A-218C, 238B, 238D relative to the upper surface of the bonding layer. Because deposition and blanket layer polishing are highly controllable to produce a uniform thickness across the surface (compared to polishing a mixed surface of the metal pads and metal lines exposed at the top dielectric layer), the recesses (e.g., the thickness T₁) of the contact regions 218A-218C, 238B, 238D can be made uniform across the surface of the substrate being processed, even for a very large substrate, e.g., 300-mm wafer. Uniform recesses of contact regions 218A-218C, 238B, 238D across the substrate facilitates better yield for hybrid bonding through more reliable metal-metal contact, and can also facilitate lower anneal temperatures to complete the hybrid bonding. In conventional hybrid bonded structures, a separate pad layer is deposited on the last metallization layer to serve as a hybrid bonding interface layer of film. In contrast, some embodiments do not include a separate pad layer and, accordingly, the hybrid bonding surface is formed without performing any separate metal deposition and metal polishing processes, resulting in considerable material and process savings. Additionally, extremely fine polishing of the dielectric layer 212 while it is a blanket layer, prior to opening the windows 224, can set the bonding surface roughness without any exposed metal during the polishing, avoiding dielectric erosion and oxide rounding around the corners of metal pads (e.g., near the interface between the dielectric layer 212 and the metal pads) that normally accompanies the simultaneous polishing of both metal and dielectric together during traditional CMP processes. These advantages and others will be apparent to the skilled artisan from discussion of the process description of FIGS. 3-4E.

FIG. 2D is a cross-sectional view of an alternative embodiment of the element 200 taken along lines A-A of FIG. 2B. In the illustrated embodiment, the metal lines 206A-206C include recessed portions 228 and protruding portions 230, where the protruding portions 230 extend above the recessed portions 228 and form the exposed portions 214 that define the contact regions 218A-218C, 238B, 238D. The dielectric layer 212 is formed over and completely covers the recessed portions 228. However, the dielectric layer 212 is not formed over the field dielectric 204 or the protruding portions 230. Instead, the upper surface of the dielectric layer 212 can be generally coplanar with the upper surface of the field dielectric 204, and the dielectric layer 212 is embedded within and includes vertical interfaces with the surrounding field dielectric 204. Accordingly, in the embodiment shown in FIG. 2D, the bonding surface 226 of the element 200 can include the field dielectric 204 and the dielectric layer 212. In some embodiments, the upper surface of the dielectric layer 212 can also be coplanar with the upper surface of the protruding portions 230 such that the bonding surface 226 also includes the contact regions 218A-218C defined by the protruding portions 230. In other embodiments, however, the protruding portions 230 can be recessed below a surface of the dielectric layer 212 and the field dielectric 204 to account for expansion of the metal that forms the metal lines 206A-206C during a later annealing step. Accordingly, in embodiments where the protruding portions 230 are recessed below the surface of the dielectric layer 212 and the field dielectric 204, the bonding surface 226 can still include the contact regions 218A-218C because they are exposed during bonding, and will grow and bond with an opposing contact region during a later annealing process.

The element 200 can also include one or more additional dielectric layers formed over the metallization layer 202. For example, in some embodiments, the element 200 includes an adhesion and/or barrier layer 232 formed between the dielectric layer 212 and the metal lines 206A-206C and also between the dielectric layer 212 and the field dielectric 204. In some embodiments, the adhesion/barrier layer 232 comprises an adhesion layer configured to improve adhesion between the dielectric layer 212 and the metal lines 206A-206C and/or the field dielectric 204. In these embodiments, the adhesion/barrier layer 232 can comprise an inorganic dielectric material, such as silicon nitride (SiN) or silicon carbonitride (SiCN). In some embodiments, the adhesion/barrier layer 232 comprises a barrier layer. In some embodiments, the barrier layer comprises a conductive barrier material, such as titanium, titanium nitride tantalum, and/or tantalum nitride. In still other embodiments, the refilled dielectric layer 212 of FIG. 2D can comprise the barrier material, and the separate barrier layer 232 can be omitted.

As with the embodiment of FIG. 2C, the dielectric layer 212 can have a thickness T₁ that is less than a thickness T₂ of the recessed portion 228 over which the dielectric layer 212 is formed, where T₁ is less than T₂. For example, in some embodiments, the T₁ can be between 0.05% and 50% of T₂. In other embodiments, however, the thickness T₁ can be a different size relative to T₂. For example, in some embodiments, between 20% and 50% of T₂, between 0.05% and 1% of T₂, between 0.05% and 20% of T₂, between 10% and 20% of T₂, between 0.5% and 10% of T₂, between 5% and 10% of T₂, between 1% and 5% of T₂, between 0.5% and 1% of T₂, less than 40% of T₂, less than 30% of T₂, less than 20% of T₂, less than 10% of T₂, less than 5% of T₂, than 2% of T₂, or less than 1% of T₂. In some embodiments, the thickness T₁ is between 2 nm and 40 nm, between 2 nm and 20 nm, between 2 nm and 10 nm, between 5 nm and 10 nm, between 2 nm and 5 nm, less than 40 num, less than 20 nm, less than 10 nm, less than 5 nm, or a value in a range defined by any of these values, and thickness T₂ is between 0.1 μm and 5 μm, between 0.5 μm and 5 μm, between 0.1 μm and 1 μm, between 1 μm and 5 μm, between 0.5 and 1 μm, greater than 5 μm, greater than 2 μm, greater than 1 μm, greater than 0.5 μm, or a value in a range defined by any of these values.

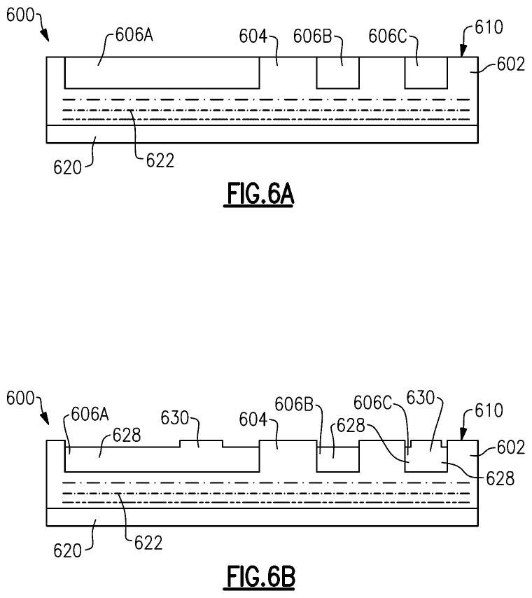

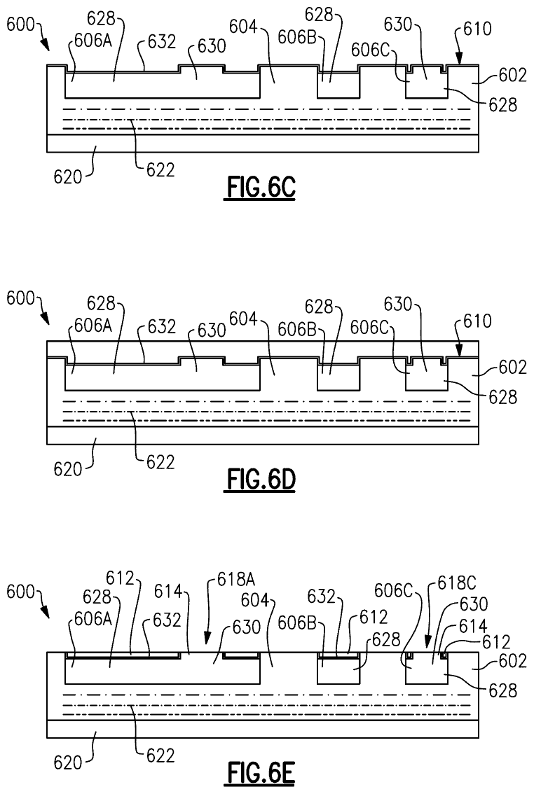

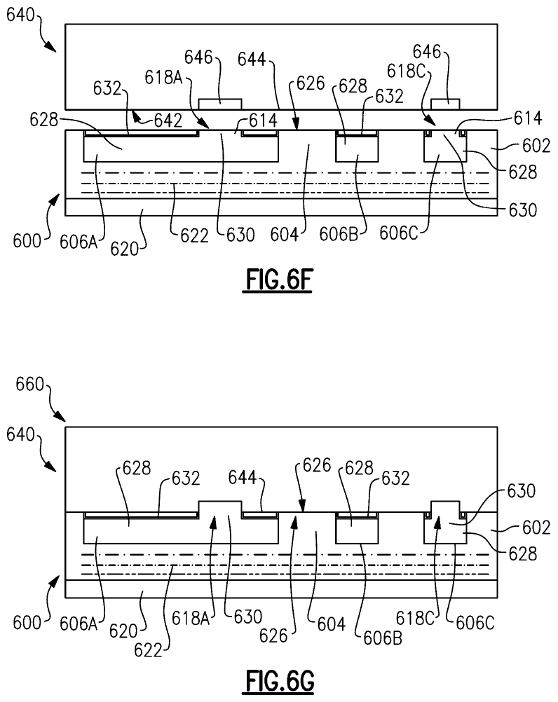

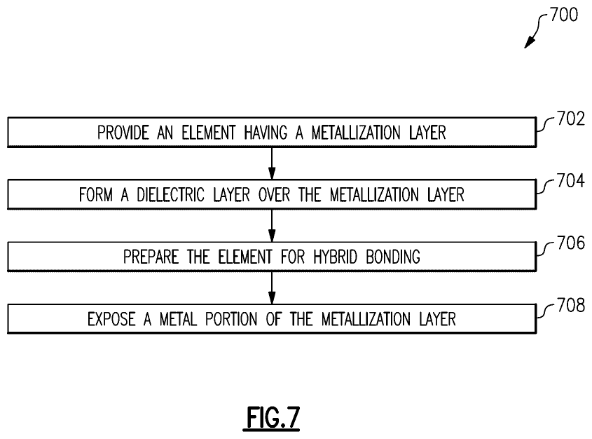

Unlike the embodiment of FIG. 2C, the etch and refill process to form the embodiment of FIG. 2D does involve polishing within both metal and dielectric exposed. However, unlike conventional hybrid bonding surfaces, the polish need not remove a metal overburden. Accordingly, a less costly and damaging polish, employing, e.g., a “barrier slurry,” can be employed, and many of the same advantages disclosed above with respect to FIG. 2C attained. These advantages and others will be apparent to the skilled artisan from discussion of the process description of FIGS. 5-6F.

FIG. 3 is a flowchart illustrating a process 300 for forming a bonded structure that includes an element that is generally similar to the element 200 shown in FIG. 2C. FIGS. 4A-4E are schematic side sectional views of microelectronic elements at various blocks of the process 300 shown in FIG. 3.

As shown in FIG. 4A, at block 302, a microelectronic element 400 is provided. The element 400, which can be generally similar to the element 200 shown and described in connection with FIG. 2A, includes a base substrate portion 420 and a metallization layer 402, representing a last or uppermost metallization level, formed on the base substrate portion 420. The metallization layer 402 includes field dielectric 404, metal lines 406A-406C formed in a surface 410 of the field dielectric 404, and one or more pads (not shown), such as test pads and/or operational pads, formed in the surface 410 of the of the field dielectric 404. The surface 410 can be a flat, polished surface that is formed using a polishing technique, such as chemical mechanical polishing (CMP). Buried metal lines 422 are formed below the metal lines 406A-406C. The metal lines 406A-406C, the buried metal lines 422, and the pads are electrically connected to active devices/circuitry within the base substrate portion 420, and can collectively represent ground, power, and/or signals lines as part of BEOL of the element 400. The metal lines 406A-406C and the field dielectric 404 can define a surface 410 of the metallization layer 402, where the metal lines 406A-406C extend in a lateral direction along the surface 410. In some embodiments, the field dielectric 404 comprises an inorganic dielectric, such as silicon oxide, silicon nitride, or silicon oxynitride, or can include carbon, such as silicon carbide, silicon oxycarbonitride, low K dielectric materials, SiCOH dielectrics, silicon carbonitride, diamond-like carbon or a material comprising a diamond surface. In some embodiments, the metal lines 406A-406C comprise a conductive metal, such as copper, aluminum, nickel, or tin. In some embodiments, the metal lines 406A-406C have a thickness between 0.1 μm and 5 μm.

As shown in FIG. 4B, at block 304, a dielectric layer 412 is formed over the metallization layer 402. In some embodiments, the dielectric layer 412 is formed by depositing a dielectric material over the surface 410 of the metallization layer 402, including over the field dielectric 404 and the metal lines 406A-406C. In some embodiments, the dielectric layer 412 completely covers the surface 410 of the element 400. In some embodiments, the dielectric layer 412 is formed from an inorganic dielectric material, such as silicon oxide or a nitrogen-containing dielectric material. For example, in some embodiments, the dielectric layer 412 comprises silicon nitride (SiN, e.g., Si₃N₄), silicon carbonitride, silicon oxycarbonitride, silicon oxynitride, or a combination thereof. In some embodiments, the dielectric layer 412 comprises a different material than the material of the field dielectric 404. In some embodiments, the dielectric layer 412 can be formed from a material that has good adhesion with the conductive metal that forms the metal lines 406A-406C. For example, in embodiments where the metal lines 406A-406C comprise copper, the dielectric layer can comprise silicon nitride or silicon carbonitride, which are known to have good adhesion to copper. In some embodiments, the dielectric layer 412 comprises multiple layers of one or more different dielectric materials. For example, in some embodiments, the dielectric layer 412 can comprise a first layer formed directly on the metallization layer 402 and a second layer formed on the first layer, where the first layer contacts the metal lines 406A-406C and the second layer forms the bonding surface 426. The first layer can include a nitrogen-containing dielectric material (e.g., silicon nitride) and the second layer can include a dielectric material that includes less (or none) nitrogen (e.g., SiO₂). In some embodiments the dielectric layer 412 can have a graded composition where the concentration of one or more elements (e.g., one or more of N, C, O, and B) is greater at the interface with the metallization layer 412 than it is at the bonding surface 426. In some embodiments, a barrier layer (e.g., a barrier layer generally similar to the adhesion/barrier layer 232 shown and described in connection with FIG. 2D) is formed over the metallization layer 402.

At block 306, after depositing the dielectric material and forming the dielectric layer 412, the dielectric layer 412 is polished to form a bonding surface 426. In some embodiments, the dielectric layer 412 is polished using a CMP process to achieve a surface roughness of, for example, 30 Å rms or less. In the illustrated embodiment, the polishing is conducted on an unpatterned or blanket layer. In some embodiments, polishing the dielectric layer 412 comprises planarizing the dielectric layer 412. In some embodiments, after polishing the dielectric layer 412, the dielectric layer 412 can have a thickness between 2 nm and 40 nm, between 2 nm and 20 nm, between 2 nm and 10 nm, between 5 nm and 10 nm, between 2 nm and 5 nm, less than 40 num, less than 20 nm, less than 10 nm, less than 5 nm, or a value in a range defined by any of these values.

As shown in FIG. 4C, at block 308, windows 424 are formed in the dielectric layer 412 to expose the exposed portions 414 of the metal lines 406A-406C, and thereby form the contact regions 418A-418C, without exposing the covered portions 416. In the cross-sectional views illustrated in FIGS. 4A-4E, the exposed portions 414 of the metal lines 406A and 406C are shown while the exposed portion 414 of the metal line 406B is not shown. The windows 424 can be formed in the dielectric layer 412 using any suitable method. For example, in some embodiments, the windows 424 are formed by depositing a photoresist over the bonding surface 426 and then patterning the photoresist to expose the portions of the dielectric layer 412 formed over the exposed portions 414. After patterning the photoresist, the exposed portions of the dielectric layer 412 can then be etched (e.g., wet or dry etched) to remove these portions of the dielectric layer 412 and form the windows 424 over the exposed portions 414. After forming the windows 424, the remaining photoresist can be stripped away to expose the rest of the dielectric layer 412.

At block 310, the bonding surface 426, including the contact regions 418A-418C, are prepared for hybrid bonding. Part or all of such preparation can be performed before opening the window(s) at block 308, such as by the polishing of block 306. In some embodiments, preparing the bonding surface 426 comprises activating the bonding surface 426. In some embodiments, activating the bonding surface 426 comprises plasma activating the bonding surface 426 by exposing the bonding surface 426 to one or plasmas, such as a nitrogen plasma and/or an oxygen plasma. In some embodiments, activating the bonding surface 426 comprises chemically activating the bonding surface. In some embodiments, preparing the bonding surface 426 for hybrid bonding comprises rinsing the bonding surface 426 to remove any particulate matter on the bonding surface 426, and then drying the bonding surface 426. Activation can sometimes be omitted, particularly if the other surface to be hybrid bonded to the bonding surface 426 is activated.

As shown in FIG. 4D, at block 312, a second element 440 is provided. In some embodiments, the second element 440 can be a reconstituted element/wafer. The second element 440 comprises a bonding surface 442, a dielectric field region 444, and conductive features 446, where the bonding surface 442 includes the conductive features 446 and the dielectric field region 444. The bonding surface 442 can be activated and prepared for hybrid bonding with element 400. In some embodiments, both the bonding surface of the second element 440 and the bonding surface 426 of the element 400 are activated. In some embodiments only one of the bonding surfaces 426, 442 is activated. The conductive features 446 comprise a conductive metal. For example, in some embodiments, the conductive metal comprises copper, aluminum, tin, nickel, gold, or an alloy of one or more of these elements. In some embodiments, the conductive features 446 comprise the same metal as the metal lines 406A-406C. In other embodiments, however, the conductive features 446 comprise a different material from the metal lines 406A-406C. In some embodiments, the dielectric field region 444 comprises an inorganic dielectric material, such as silicon oxide, silicon nitride, silicon oxynitride, and can include carbon, such as silicon carbide, silicon oxycarbonitride, low K dielectric materials, SiCOH dielectrics, silicon carbonitride, diamond-like carbon, a material comprising a diamond surface, or combinations thereof. In some embodiments, the dielectric field region 444 comprises the same dielectric material as the dielectric layer 412.

In some embodiments, the second element 440 can have a structure that is generally similar to the structure of element 400, which can also be referred to as the first element 400. For example, in some embodiments, the conductive features 446 can be formed from exposed portions of metal lines in a BEOL layer and the field dielectric 444 is a part of a dielectric layer formed over the BEOL layer. In other embodiments, the second element 440 can have a structure that is different than the structure of element 400. For example, in some embodiments, the second element 440 can have a metallization layer (e.g., an RDL) formed over BEOL layers and the conductive features 446 and field dielectric 444 are part of that metallization layer. In some embodiments, one or more of the conductive features 446 can be a bond pad that is electrically connected to a TSV (or other type of via) that extends through the second element 440. In some embodiments, one or more the conductive features 446 can be a portion of the TSV. In some embodiments, the second element 440 can have a structure generally similar to the structure of element 200 shown in FIG. 2D. In some embodiments, the conductive features 446 are recessed below the dielectric field region 444. In other embodiments, the conductive features 446 are generally coplanar with the dielectric field region 444 or protrude above (or below in the orientation of FIG. 4D) the dielectric field region 444. In general, the second element 440 can have any structure that is suitable for hybrid bonding with the element 400.

As shown in FIG. 4E, at block 314, the element 400 is hybrid bonded to the second element 440 to form bonded structure 460. In some embodiments, the element 400 is hybrid bonded to the second element 440 without an intervening adhesive. The element 400 can be hybrid bonded to the second element 440 by contacting the bonding surface 442 of the second element to the bonding surface 426 so that the dielectric layer 412 and the dielectric field region 444 contact each other, which can cause chemical bonds (e.g., covalent bonds) to occur spontaneously between the dielectric material of the dielectric layer 412 and the dielectric material of the dielectric field region 444, even at room temperature and without external pressure beyond initiating contact. In some embodiments, hybrid bonding the element 400 to the second element 440 can include annealing the elements 400 and 440 to cause the contact regions 418A-418C to contact conductive features 446. In some embodiments, annealing the elements 400 and 440 causes one or both of the contact regions 418A-418C and the conductive features 446 to expand and contact the opposing metal surface, resulting in the materials of the contact regions 418A-418C inter-diffusing with the materials of the opposing conductive features 446. In some embodiments, annealing the elements 400 and 440 can also increase the strength of the chemical bonds between the dielectric layer 412 and the dielectric field region 444.

After hybrid bonding the element 400 to the second element 440 to form the bonded structure 460, the bonded structure 460 can undergo additional processing. For example, in some embodiments, the bonded structure 460 can be singulated to form one or more singulated bonded structures and/or can be bonded to one or more other elements (e.g., dies, substrates, wafers, etc.). In some embodiments, the additional processing can include thinning the bonded structure 460 (either before or after being singulated and/or bonded to another element or after). For example, in some embodiments, the backsides of one or both of elements 400, 440 (e.g., the sides of the elements 400, 440 opposite from the bonding surfaces 426, 442) can be thinned. In some embodiments, after thinning, the backsides of one or both of the elements 400, 440 can be etched to reveal TSVs or other metallization structures within the elements 400, 440. In some embodiments, the additional processing can include processing the backside of one or both of the elements 400, 440 to form one or more bonding surfaces. In some embodiments, after forming the one or more bonding surfaces, a conductive layer can be deposited over any metallization structures (e.g., TSVs) exposed at the bonding surface(s), and this conductive layer can comprise a metal having a melting point that is less than 350° C. In some embodiments, a conductive barrier layer can be formed between one or more of the exposed metallization structures and the deposited conductive layer. In some embodiments, one or more other elements (e.g., dies, substrates, wafers, etc.) can be bonded to the backside (e.g., to the bonding surface or the conductive layer) of one or both of the elements 400, 440.

FIG. 5 is a flowchart illustrating a process 500 for forming a bonded structure that includes the element 200 and dielectric layer 212 shown in FIG. 2D. FIGS. 6A-6F are schematic side sectional views of microelectronic elements at various blocks of the process 500 shown in FIG. 5.

As shown in FIG. 6A, at block 502, a microelectronic element 600 is provided. The element 600, which can be generally similar to the element 200 shown and described in connection with FIGS. 2A and 4A, includes a base substrate portion 620 and a metallization layer 602 formed on the base substrate portion 620. The metallization layer 602, representing a last or uppermost metallization level, includes field dielectric 604, metal lines 606A-606C formed in the field dielectric 604, and one or more pads (not shown), such as test and/or operational pads, formed in the field dielectric 604. The buried metal lines 622 are formed below the metal lines 606A-606C. The metal lines 606A-606C, the buried metal lines 622, and the test pads are electrically connected to active devices/circuitry within the base substrate portion 620, and can collectively represent ground, power, and/or signals lines as part of BEOL of the element 600. In some embodiments, the field dielectric 604 comprises an inorganic dielectric, such as silicon oxide, silicon nitride, or silicon oxynitride, or can include carbon, such as silicon carbide, silicon oxycarbonitride, low K dielectric materials, SiCOH dielectrics, silicon carbonitride, diamond-like carbon or a material comprising a diamond surface. The metal lines 606A-606C and the field dielectric 604 can define a surface 610 of the metallization layer 602, where the metal lines 606A-606C extend in a lateral direction along the surface 610. In some embodiments, the surface 610 can be a flat/polished surface that is formed by polishing the field dielectric 604, the metal lines 606A-606C, and the one or more pads using a polishing technique (e.g., CMP). In some embodiments, the metal lines 606A-606C comprise a conductive metal, such as copper, aluminum, tin, nickel, or an alloy of one or more of these elements. In some embodiments, the metal lines 606A-606C have a thickness between 0.1 μm and 5 μm.

As shown in FIG. 6B, at block 504, the metallization layer 602 is patterned to form recessed portions 628 and protruding portions 630 in the metal lines 606A-606C. Although not shown in this cross section, the entirety of any test pads (e.g., any probe pads) can also be recessed, and portions of any operational pads can protrude or include protruding portions. The protruding portions 630 extend above the recessed portions 628 but can be generally coplanar with, or slightly recessed relative to, the surface 610 of the field dielectric 604. In contrast, the recessed portions 628 are generally recessed below the surface of the field dielectric 604. In some embodiments, after patterning the metallization layer 602, a distance between the top or exposed surface of the protruding portions 630 and the top or exposed surface of the recessed portions 628 can be between about 10 nm and about 1000 nm, between about 10 nm and about 200 nm, between about 50 nm and about 600 nm, between about 100 nm and 1000 nm, between about 200 nm and about 400 nm, between about 50 nm and about 200 nm, between about 100 nm and about 200 nm, or a value in a range defined by any of these values. Additionally, after patterning the metallization layer 602, the recessed portions 628 can have a thickness that is between 0.1 μm and 5 μm, between 0.5 μm and 5 μm, between 0.1 μm and 1 μm, between 1 μm and 5 μm, between 0.5 and 1 μm, greater than 5 μm, greater than 2 μm, greater than 1 μm, greater than 0.5 μm, or a value in a range defined by any of these values.

In some embodiments, the recessed portions 628 and protruding portions 630 are patterned using a selective etching process. In these embodiments, a resist or other masking material is deposited over the metallization layer 602 and then patterned to reveal portions of the metal lines 606A-606C (e.g., the portions of the metal lines 606A-606C that are above the recessed portions 628) without revealing other portions of the metal lines 606A-606C (e.g., the portions of the metal lines 606A-606C that are above the protruding portions 630) and without revealing the field dielectric 604. In some embodiments, the resist is also patterned to reveal any pads formed in the metallization layer 602. After patterning the resist, an etchant is applied to the element 600 to selectively etch, and therefore remove, the revealed portions of the metal lines 606A-606C and form the recessed portions 628. The etchant is highly selective for metal and typically does not (or does not substantially or significantly) etch the dielectric material that forms the field dielectric 604. Additionally, the presence of the masking material over the protruding portions 630 ensures that the etchant is not applied to the protruding portions 630, which means that the etchant does not etch or remove the metal that forms the protruding portions 630. In some embodiments, applying the etchant to the element 600 also comprises applying the etchant to any pads formed in the metallization layer 602 and removing some of the metal that forms the pads so that the pads are also recessed below the field dielectric 604.

As shown in FIG. 6C, at block 506, an adhesion and/or barrier layer 632 is deposited over the metallization layer 602. The adhesion and/or barrier layer 632 is deposited over the metallization layer 602 such that it completely covers the metallization layer 602, including the field dielectric 604 and the metal lines 606A-606C (and any pads also included in the metallization layer 602). In some embodiments, the adhesion/barrier layer 632 is configured to improve adhesion between the metal that forms the metal lines 606A-606C (and pads) and a subsequent dielectric layer formed over the adhesion/barrier layer 632. In some embodiments, the adhesion and/or barrier layer 632 comprises a barrier layer that includes a conductive barrier material, such as titanium, titanium nitride, tantalum, and/or tantalum nitride. As noted with respect to FIG. 2D, such a layer can be omitted depending upon the composition of a later-deposited filler dielectric. The adhesion/barrier layer 632 can be formed from an inorganic dielectric material. For example, in some embodiments, the adhesion/barrier layer 632 can comprise silicon nitride or silicon carbonitride. In some embodiments, the adhesion/barrier layer 632 can comprise a different material from the field dielectric 604. In some embodiments, the adhesion/barrier layer 632 can have a thickness of between 1 nm and 20 nm.

As shown in FIG. 6D, at block 508, dielectric layer 612 is deposited over the adhesion/barrier layer 632 (if present). The dielectric layer 612 is deposited over the adhesion/barrier layer 632 such that it completely covers adhesion/barrier layer 632 and is formed over the entire metallization layer 602, including the field dielectric 604 and the metal lines 606A-606C (and any pads also included in the metallization layer 602). In some embodiments, the dielectric layer 612 is formed from an inorganic dielectric material, such as a nitrogen-containing dielectric material, and can serve adhesion and/or barrier functions such that the adhesion/barrier layer 632 can be omitted. For example, in some embodiments, the dielectric layer 612 comprises silicon nitride (SiN, e.g., Si₃N₄), silicon carbonitride (SiCN), silicon oxycarbonitride (SiOCN), silicon oxynitride (SiON), or a combination thereof. In some embodiments, the dielectric layer 612 is formed from the same or similar material as the field dielectric 604, such as a material comprising silicon oxide. In other embodiments, however, the dielectric layer 612 is formed from a different material the field dielectric 604. In some embodiments, the dielectric layer 612 can be deposited over the adhesion/barrier layer 632 such that it has a thickness of about 10 nm to about 2 μm. In some embodiments, the dielectric layer 612 is formed such that it at least fills the recessed portions 628 of the metal lines 606A-606C. While shown with a flat upper surface, the skilled artisan will appreciate that, if deposited conformally (e.g., by CVD or PVD), the dielectric layer 612 may have an undulating surface after deposition. In some embodiments, the dielectric layer 612 can include multiple layers of one or more dielectric materials. In embodiments where the adhesion and/or barrier layer 632 is not present, the dielectric layer 612 can include a first layer formed directly on the metallization layer 602 and a second layer formed on the first layer, where the first layer can comprise an adhesion layer.

After depositing the adhesion/barrier layer 632 and the dielectric layer 612 over the metallization layer 602, the protruding portion 630 of the metal lines 606A-606C can be completely covered by dielectric material, which means that the metal lines 606A-606C would be unable to participate in hybrid bonding with another element. To facilitate the element 600 participating in hybrid bonding, as shown in FIG. 6E, at block 510, the element 600 is planarized and polished to expose the protruding portions 630, which define contact regions 618A-618C, and form a bonding surface 626.

The bonding surface 626 includes the field dielectric 604, the dielectric layer 612, the adhesion/barrier layer 632 (if present), and the contact regions 618A-618C, which are formed from the exposed portions 614 of protruding portions 630 of the metal lines 606A-606C. Accordingly, planarizing and thinning the element 600 comprises completely removing the portions of the dielectric layer 612 and the adhesion/barrier layer 632 that are formed over the protruding portions 630 and the field dielectric 604 until the protruding portions 630 and the portions of the field dielectric 604 that neighbor or surround the protruding portions 630 are exposed. Only dielectric overburden (not metal overburden) is removed in this planarization, such that a simpler and faster polishing process (e.g., employing a barrier slurry composition) can be employed. After planarizing and thinning the element 600, the surface of the dielectric layer 612 can be generally coplanar with the field dielectric 604. Additionally, in some embodiments, after planarizing and thinning the element 600, the thickness of the dielectric layer 612 can be approximately equal to a distance between the field dielectric 604 and the recessed portions 628. In some embodiments, after planarizing and thinning the element 600, the exposed portions 614 of the protruding portions 630 can be recessed below the surface of the field dielectric 604. In some embodiments, the exposed portions 614 of the protruding portions 630 can be recessed below the surface of the field dielectric by 15 nm or less, 10 nm or less, 5 nm or less, even as low as about 2 nm, or a value in a range defined by any of these values.

In some embodiments, planarizing and thinning the element 600 also comprises thinning the protruding portions 630 and the field dielectric 604. As previously discussed, after the recessed portions 628 and the protruding portions 630 are formed by patterning the metal lines 606A-606C, a first distance between the surface of the protruding portions 630 and the surface of the recessed portions 628 can be between about 10 nm and about 1000 nm. Accordingly, in embodiments where planarizing and thinning the element 600 comprises thinning the protruding portions 630 and the field dielectric 604, after planarizing and thinning the element 600, the surface of the protruding portions 630 (i.e., the exposed portions 614 of the metal lines 606A-606C) can be above the surface of the recessed portions 628 by a second distance that is less than the first distance. For example, in some embodiments, after planarizing and thinning the element 600, the distance between the top or exposed surface of the protruding portions 630 and the top surface of the recessed portions 628 is between 10 nm and 1000 nm, between 5 nm and 500 nm, between 5 nm and 100 nm, between 2 nm and 50 nm, between 2 nm and 40 nm, between 2 nm and 20 nm, between 2 nm and 10 nm, between 5 nm and 10 nm, between 2 nm and 5 nm, less than 1000 nm, less than 500 nm, less than 100 nm, less than 40 num, less than 20 nm, less than 10 nm, less than 5 nm, or a value in a range defined by any of these values. Additionally, because the surface of the dielectric layer 612 is coplanar with the surface of the field dielectric 604, after planarizing and thinning the element 600, the dielectric layer 612 can have a thickness that is also between 10 nm and 1000 nm, between 5 nm and 500 nm, between 5 nm and 100 nm, between 2 nm and 50 nm, between 2 nm and 40 nm, between 2 nm and 20 nm, between 2 nm and 10 nm, between 5 nm and 10 nm, between 2 nm and 5 nm, less than 1000 nm, less than 500 nm, less than 100 nm, less than 40 num, less than 20 nm, less than 10 nm, less than 5 nm, or a value in a range defined by any of these values.

In some embodiments, planarizing and thinning the element 600 to form the bonding surface 626 comprises polishing the bonding surface 626, including polishing the contact regions 618A-618C, the field dielectric 604, and the dielectric layer 612. For example, in some embodiments, the planarizing and thinning process is performed using a CMP process that results in the bonding surface 626 having a surface roughness of, for example, 30 Å rms or less.

At block 512, the bonding surface 626 is prepared for hybrid bonding. Preparation for hybrid bonding can at least include fine polishing to leave a smooth surface, which can be part of planarization in block 510. In some embodiments, preparing the bonding surface 626 for hybrid bonding comprises activating the bonding surface 626. In some embodiments, activating the bonding surface 626 comprises plasma activating the bonding surface 626 by exposing the bonding surface 626 to one or plasmas, such as a nitrogen plasma and/or an oxygen plasma. In some embodiments, activating the bonding surface 626 comprises chemically activating the bonding surface. In some embodiments, preparing the bonding surface 626 for hybrid bonding comprises rinsing the bonding surface 626 to remove any particulate matter on the bonding surface 626, and then drying the bonding surface 626.

In some embodiments, preparing the bonding surface 626 for hybrid bonding includes polishing the bonding surface 626 (e.g., using a CMP process) before activating the bonding surface 626. In other embodiments, however, preparing the bonding surface 626 for hybrid bonding does not include a separate polishing process. For example, as previously described, in some embodiments, the planarizing and thinning process of block 510 includes polishing the bonding surface 626. In these embodiments, the process of preparing the bonding surface may not include an additional polishing step. However, in embodiments where the planarizing and thinning process of block 510 does not include polishing the bonding surface 626, preparing the bonding surface 626 for hybrid bonding can comprise polishing the bonding surface 626. Additionally, even when the planarizing and thinning process of block 510 does include polishing the bonding surface 626, the process of preparing the bonding surface 626 for hybrid bonding can include an additional polishing process.

As shown in FIG. 6F, at block 514, a second element 640 is provided. The second element 640 comprises a bonding surface 642, a dielectric field region 644, and conductive features 646, where the bonding surface 642 includes the conductive features 646 and the dielectric field region 644. The bonding surface 642 can be activated and prepared for hybrid bonding with element 600. In some embodiments, both the bonding surface of the second element 640 and the bonding surface 626 of the element 600 are activated. In some embodiments, only one of the bonding surfaces 626, 642 is activated. The conductive features 646 comprise a conductive metal. For example, in some embodiments, the conductive metal comprises copper, aluminum, tin, nickel, gold, or an alloy of one or more of these elements. In some embodiments, the conductive features 646 comprise the same metal as the metal lines 606A-606C. In other embodiments, however, the conductive features 646 comprise a different metal. In some embodiments, the dielectric field region 644 comprises an inorganic dielectric material, such as silicon oxide, silicon nitride, silicon oxynitride, and can include carbon, such as silicon carbide, silicon oxycarbonitride, low K dielectric materials, SiCOH dielectrics, silicon carbonitride, diamond-like carbon, a material comprising a diamond surface, or combinations thereof. In some embodiments, the dielectric field region 644 comprises the same dielectric material as the dielectric layer 612.

In some embodiments, the second element 640 can have a structure that is generally similar to the structure of the element 600, which can also be referred to as the first element 600. For example, in some embodiments, the conductive features 646 can be formed from exposed portions of metal lines in a BEOL layer and the field dielectric 644 is a part of a dielectric layer formed over the BEOL layer. In other embodiments, the second element 640 can have a structure that is different than the structure of the element 600. For example, in some embodiments, the second element 640 can have a metallization layer (e.g., an RDL) formed over a BEOL layer and the conductive features 646 and field dielectric 644 are part of that metallization layer. In some embodiments, one or more of the conductive features 646 can be a bond pad that is electrically connected to a TSV (or other type of via) that extends through the second element 640. In some embodiments, one or more the conductive features 646 can be a portion of the TSV. In some embodiments, the second element 640 can have a structure generally similar to the structure of elements 200 shown in FIGS. 2C or 2D. In some embodiments, the conductive features 646 are recessed below the dielectric field region 644. In other embodiments, the conductive features 646 are generally coplanar with the dielectric field region 644 or protrude past the dielectric field region 644. In general, the second element 640 can have any structure that is suitable for hybrid bonding with the element 600. In some embodiments, the second element 640 is a reconstituted wafer/element.

As shown in FIG. 6G, at block 516, the element 600 is hybrid bonded to the second element 640 to form bonded structure 660. In some embodiments, the element 600 is hybrid bonded to the second element 600 without an intervening adhesive. The element 600 can be hybrid bonded to the second element 640 by contacting the bonding surface 642 of the second element to the bonding surface 626 so that the dielectric layer 612 and the dielectric field region 644 contact each other, which can cause chemical bonds (e.g., covalent bonds) to occur spontaneously between the dielectric material of the dielectric layer 612 and the field dielectric 604 and the dielectric material of the dielectric field region 644, even at room temperature and without external pressure beyond initiating contact. In some embodiments, hybrid bonding the element 600 to the second element 640 can include annealing the elements 600 and 640 to cause the contact regions 618A-618C to contact conductive features 646. In some embodiments, annealing the elements 600 and 640 causes one or both of the contact regions 618A-618C and the conductive features 646 to expand and contact the opposing metal surface, resulting in the materials of the contact regions 618A-618C inter-diffusing with the materials of the opposing conductive features 646. In some embodiments, annealing the elements 600 and 640 can also increase the strength of the chemical bonds between the dielectric layer 612 and the dielectric field region 644.

After hybrid bonding the element 600 to the second element 640 to form the bonded structure 660, the bonded structure 660 can undergo additional processing. For example, the bonded structure 660 can be singulated to form one or more singulated bonded structures and/or can be bonded to one or more other elements (e.g., dies, substrates, wafers, etc.).

In the embodiment illustrated in FIGS. 6A-6G, the element 600 includes the adhesion and/or barrier layer 632 between the dielectric layer 612 and the metal lines 606A- 606C (and between the dielectric layer 612 and the pads). In other embodiments, however, the element 600 does not include the adhesion/barrier layer 632. In these embodiments, the dielectric layer 612 is formed directly on the metallization layer 602 such that the dielectric layer 612 directly contacts the metallization layer 612. Accordingly, in embodiments where the element 600 does not include the adhesion/barrier layer 632, block 506 of process 500 can be omitted.

FIG. 7 is a flowchart illustrating another process for forming an element that is generally similar to the elements 200 shown in FIGS. 2B-2D.

At block 702, an element is provided. The element, which can be generally similar to the element 200 shown and described in connection with FIG. 2A, can include a base substrate portion and a metallization layer formed on the base substrate portion. The metallization layer can include a field dielectric, metal lines formed in a surface of the field dielectric, and can also include one or more pads (such as test pads or operational pads) formed in the surface of the of the field dielectric. Buried metal lines can be formed below the metal lines. The metal lines, the buried metal lines, and the pads are electrically connected to active devices/circuitry within the base substrate portion. In some embodiments, the field dielectric comprises an inorganic dielectric, such as silicon oxide, silicon nitride, or silicon oxynitride, and can include carbon, such as silicon carbide, silicon oxycarbonitride, low K dielectric materials, SiCOH dielectrics, silicon carbonitride, diamond-like carbon or a material comprising a diamond surface. In some embodiments, the metal lines comprise a conductive metal, such as copper or aluminum. In some embodiments, the metal lines have a thickness between 0.1 μm and 5 μm.

The metal lines and the field dielectric define a surface of the metallization layer, where the metal lines extend in a lateral direction along the surface. In some embodiments, the metal lines and any pads are coplanar with the field dielectric. In other embodiments, the metal lines include protruding portions and recessed portions, where the protruding portions are coplanar with the field dielectric while the recessed portions (and the pads) are recessed below the protruding portions and the field dielectric.

At block 704, a dielectric layer is formed over the metallization layer. The dielectric layer is formed by depositing a dielectric material over the surface of the metallization layer, including over the field dielectric and the metal lines. In some embodiments, the dielectric layer completely covers the surface of the element. In some embodiments, the dielectric layer is formed from an inorganic dielectric material, such as a nitrogen-containing dielectric material. For example, in some embodiments, the dielectric layer comprises silicon nitride (SiN, e.g., Si₃N₄), silicon carbonitride, silicon oxycarbonitride, silicon oxynitride, or a combination thereof. In some embodiments, the dielectric layer comprises a different material than the field dielectric. In some embodiments, the dielectric layer can be formed from a material that has good adhesion with the conductive metal that forms the metal lines. The dielectric layer can be formed such that it has a thickness between 2 nm and 80 nm, between 2 nm and 40 nm, between 2 nm and 20 nm, between 2 nm and 10 nm, between 5 nm and 10 nm, between 5 nm and 20 nm, between 2 nm and 5 nm, less than 40 num, less than 20 nm, less than 10 nm, less than 5 nm, or a value in a range defined by any of these values.

In some embodiments, before forming the dielectric layer over the metallization layer, an additional dielectric layer is formed over the metallization layer. For example, in some embodiments, an adhesion and/or barrier layer is formed on the metallization layer and then the dielectric layer is formed over the adhesion and/or barrier layer. In other embodiments, the dielectric layer is formed directly on the metallization layer.

At block 706, after forming the dielectric layer over the metallization layer, the element is prepared for hybrid bonding. In some embodiments, preparing the element for hybrid bonding comprises preparing the bonding surface of the element for hybrid bonding. In some embodiments, preparing the element for hybrid bonding comprises thinning, planarizing, and/or polishing the dielectric layer after depositing the dielectric material over the metallization layer. In some embodiments, preparing the element for hybrid bonding comprises activating a bonding surface of the element by exposing the bonding surface to one or more plasmas, such as a nitrogen plasma and/or an oxygen plasma. In some embodiments, preparing the element for hybrid bonding comprises rinsing the bonding surface to remove any particulate matter on the bonding surface, and then drying the bonding surface.

At block 708, a metal portion of the metallization layer is exposed. In some embodiments, the metal portion of the metallization layer is exposed by patterning a window through the dielectric layer (e.g., using an etching process), and can be performed after at least part of block 706. In some embodiments, the metal portion of the metallization layer is exposed by planarizing the dielectric layer until a portion of the metallization layer (e.g., a protruding portion) is exposed while other portions of the metallization layer (e.g., a recessed portion) are still covered by the dielectric layer. In some embodiments, the metal portion of the metallization layer is exposed after the dielectric layer is thinned, planarized, and/or polished. In other embodiments, the metal portion of the metallization layer is exposed as part of the thinning, planarizing, and/or polishing process of block 706.

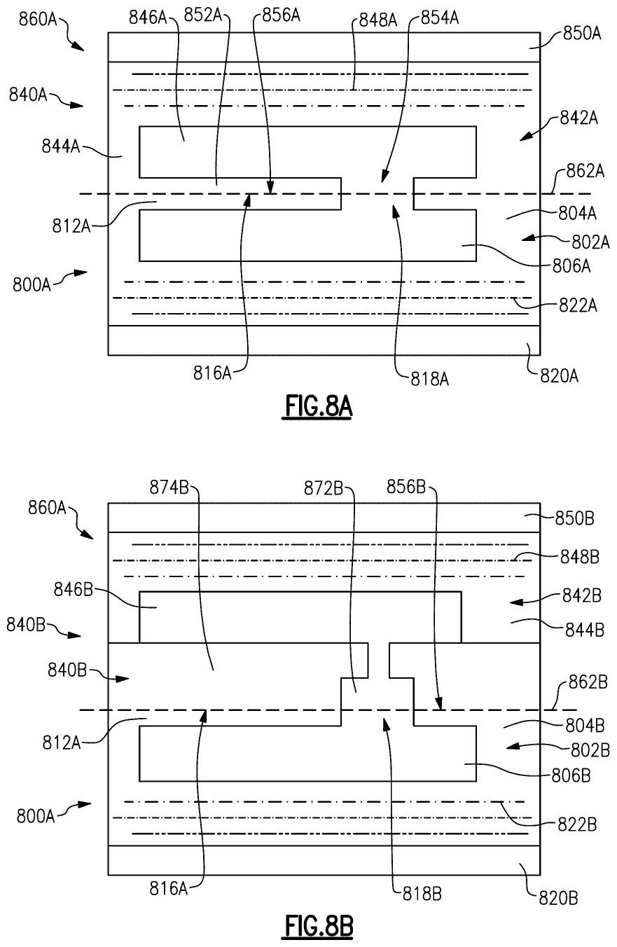

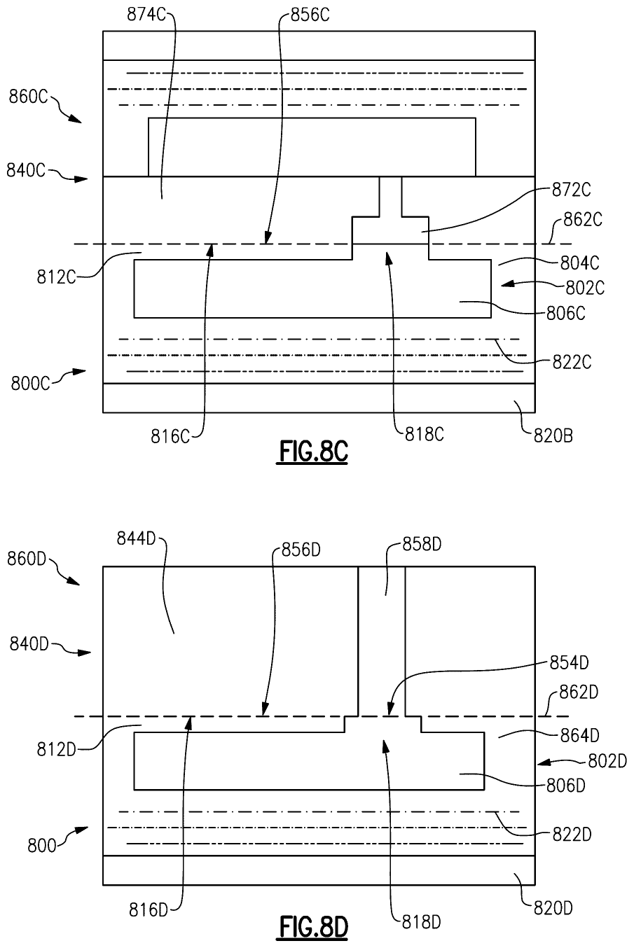

After the process of FIG. 7, the element can be hybrid bonded to another element. FIGS. 8A-8D schematically illustrate cross-sectional views of various bonded structures 860A-860D that each include a first element 800A-800D hybrid bonded to a corresponding second element 840A-840D, where each of the first elements 800A-800D are generally similar to any of the elements 200, 400, 600, shown and described in connection with FIGS. 2B-2D, 4A-4E, and 6A-6F. Specifically, each of the first elements 800A-800D has a metallization layer 802A-802D and a base substrate portion 820A-820D, where the metallization layer 802A-802D has a field dielectric 804A-804D, a metal line 806A-806D formed in the field dielectric 804A-804D, buried metal lines 822A-822D formed below the metal line 806A-806D, and a dielectric layer 812A-812D formed over the metal line 806A-806D. The metal line 806A-806D has a contact region 818A-818D that is surrounded by the dielectric layer 812A-812D. The contact region 818A-818D extends towards the second element 840A-840D and is directly bonded to the contact region 854A-854D of the second element 840A-840D with a metal-to-metal direct bond at the bond interface 862A-862D.

The first elements 800A-800D each have a first non-conductive bonding surface 816A-816D that is directly bonded to a second non-conductive bonding surface 856A-856D of the corresponding second element 840A-840D at the bond interface 862A-862D. In some embodiments (e.g., embodiments where the first element 800A-800D has a structure that is generally similar to element 200 shown in FIG. 2C), the dielectric layer 812A-812D completely covers the field dielectric 804A-804D. In these embodiments, the first non-conductive bonding surface 816A-816D includes the dielectric layer 812A-812D. In other embodiments (e.g., embodiments where the first element 800A-800D has a structure that is generally similar to element 200 shown in FIG. 2D), the dielectric layer 812A-812D is coplanar with the field dielectric 804A-804D. In these embodiments, the first non-conductive bonding surface 816A-816D includes the dielectric layer 812A-812D and the field dielectric 804A-804D.

FIG. 8A schematically illustrates a cross-sectional view of a bonded structure 860A that includes a first element 800A hybrid bonded to a second element 840A at a bond interface 862A. In this embodiment, the second element 840A also has a structure that is generally similar to any of the elements 200, 400, 600 shown and described in connection with FIGS. 2B-2D, 4A-4E, and 6A-6F. Specifically, the second element 840A has a metallization layer 842A and a base substrate portion 850A, where the metallization layer 842A has a field dielectric 844A and a metal line 846A formed in the field dielectric 844A. Buried metal lines 848A are formed below the metal line 846A, and a dielectric layer 852A is formed over the metal line 846A. The metal line 846A has a contact region 854A that is surrounded by the dielectric layer 852A. The contact region 854A extends towards the first element 800A and is directly bonded to the contact region 818A of the first element 800A with a metal-to-metal direct bond at the bond interface 862A.

The second element 840A has a second non-conductive bonding surface 856A that is directly bonded to the first non-conductive bonding surface 816A of the first element 800A without an intervening adhesive at the bond interface 862A. In some embodiments (e.g., embodiments where the second element 840A has a structure that is generally similar to element 200 shown in FIG. 2C), the dielectric layer 852A completely covers the field dielectric 844A. In these embodiments, the second non-conductive bonding surface 856A includes the dielectric layer 852A. In other embodiments (e.g., embodiments where the second element 840A has a structure that is generally similar to element 200 shown in FIG. 2D), the dielectric layer 852A is coplanar with the field dielectric 844A. In these embodiments, the second non-conductive bonding surface 856A includes the dielectric layer 852A and the field dielectric 844A.

FIG. 8B schematically illustrates a cross-sectional view of a bonded structure 860B that includes a first element 800B hybrid bonded to a second element 840B at a bond interface 862B. In this embodiment, the second element 840B has a metallization layer 842B and a base substrate portion 850B, where the metallization layer 842B has a field dielectric 844B and a metal line 846B formed in the field dielectric 844B. Buried metal lines 848B are formed below the metal line 846B. The second element 840B also has a bonding layer 870B formed on the metallization layer 842B. The bonding layer 870B includes a bond pad 872B and a dielectric layer 874B, where the dielectric layer 874B surrounds the bond pad 872B. The bond pad 872B, which can comprise the same type of metal as the metal line 806B (e.g., copper), defines a contact region 854B and is directly bonded to the contact region 818B with a metal-to-metal direct bond at the bond interface 862B. In some embodiments, the bond pad 872B and the contact region 818B can have different sizes and/or shapes. The dielectric layer 874B, which can be formed from an inorganic dielectric material, defines a second non- conductive bonding surface 856B that is directly bonded to the first non-conductive bonding surface 816B of the first element 800B without an intervening adhesive at the bond interface 862B. In some embodiments, the dielectric layer 874B is formed from the same inorganic dielectric material that the dielectric layer 812B and/or field dielectric 804B is formed from. In other embodiments, the dielectric layer 874B can be formed from a different inorganic dielectric material than the inorganic dielectric material that forms one or both of the dielectric layer 812B and field dielectric 804B.

FIG. 8C schematically illustrates a cross-sectional view of a bonded structure 860C that includes a first element 800C hybrid bonded to a second element 840C at a bond interface 862C. The second element 840C can have a structure that is generally the same as the structure of the second element 840B shown in FIG. 8B except that the bond pad 872C comprises a different metal from the metal line 806C. For example, in embodiments where the metal line 806C comprises aluminum, the bond pad 872C can comprise copper. Similarly, in embodiments where the metal line 806C comprises copper, the bond pad 872C can comprise aluminum. In some embodiments, the bond pad 872C and the contact region 818C can have different sizes and/or shapes. The dielectric layer 874C, which can be formed from an inorganic dielectric material, defines a second non-conductive bonding surface 856C that is directly bonded to the first non-conductive bonding surface 816C of the first element 800C without an intervening adhesive at the bond interface 862C. In some embodiments, the dielectric layer 874C is formed from the same inorganic dielectric material from which the dielectric layer 812C and/or field dielectric 804C is formed. In other embodiments, the dielectric layer 874C can be formed from a different inorganic dielectric material than the inorganic dielectric material that forms one or both of the dielectric layer 812C and field dielectric 804C.

FIG. 8D schematically illustrates a cross-sectional view of a bonded structure 860D that includes a first element 800D hybrid bonded to a second element 840D at a bond interface 862C. In the illustrated embodiment, the second element 840D includes a field dielectric 844D and a via 858D formed in the field dielectric 844D. The via 858D, which extends through the field dielectric 844D, defines a contact region 854D and is directly bonded to the contact region 818D with a metal-to-metal direct bond at the bond interface 862D. The field dielectric 844D defines a second non-conductive bonding surface 856D that is directly bonded to the first non-conductive bonding surface 816D of the first element 800D without an intervening adhesive at the bond interface 862D.

In some embodiments, the via 858D comprises a TSV that extends completely through the second element 840D and can also extend through bulk substrate material (not shown) of the second element 840D. The TSV may or may not be electrically connected to circuitry (e.g., active circuitry or devices, metallization layers, etc.) within the second element 840D, and can be electrically connected to circuitry in a third element (not shown) connected to the second element 840D. In some embodiments, the via 858D comprises blind via that is electrically connected to circuitry that is not adjacent to the bond interface 862D.

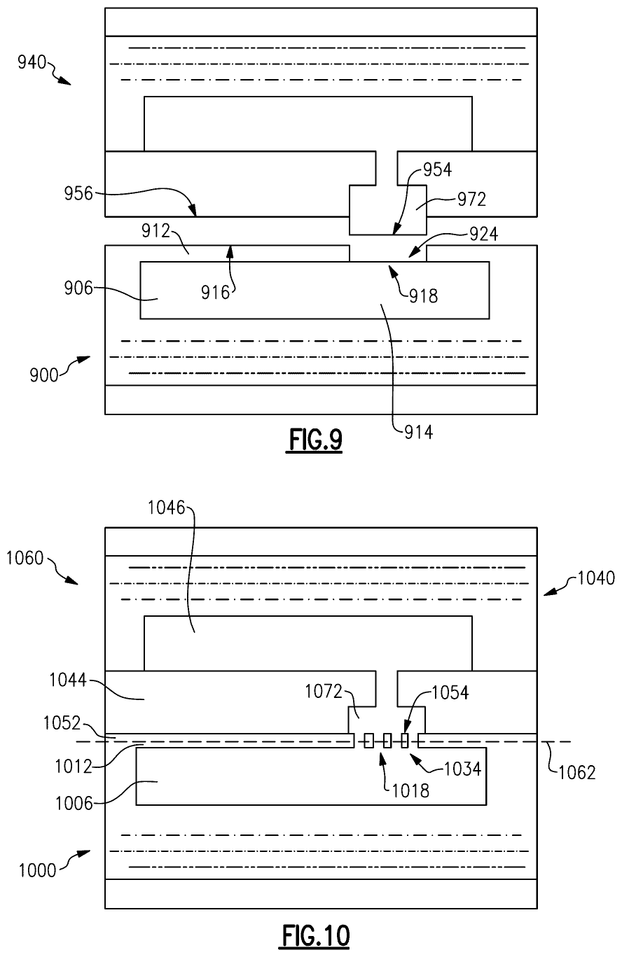

As previously described, in some embodiments, the contact regions of the first and second elements can be recessed below their respective bonding surfaces prior to direct bonding such that, when the non-conductive bonding surfaces are brought into contact, the opposing contact regions are separated from each other by a gap before the elements are annealed. In other embodiments, however, one of the elements can have a contact region that protrudes beyond its associated non-conductive bonding surface. FIG. 9 schematically illustrates a schematic side sectional view of a first element 900 and a second element 940 that is positioned over the first element 900 and ready for hybrid bonding with the first element 900, where the second element 940 has a structure generally similar to second elements 840B or 840C except that the bond pad 972 protrudes beyond the second non-conductive bonding surface 956. The first element 900 can be generally similar to any of the elements 200, 400, 600 shown and described in connection with FIGS. 2B-2D, 4A-4E, and 6A-6F.

When the second element 940 is brought into contact with the first element 900 such that the first non-conductive bonding surface 916 contacts the second non-conductive bonding surface 956, the bond pad 972 can extend into the window 924 formed in the dielectric layer 912 over the exposed portion 914 of the metal line 906. Upon annealing the first and second elements 900, 940, the bond pad 972 can expand and contact the contact region 918 formed from the exposed portion 914. With this arrangement, the gap between the contact region 954 of the second element 940 and the contact region 918 of the first element 900 can be reduced (i.e., compared to embodiments where the bond pad does not protrude beyond the second non-conductive bonding surface prior to annealing), which can allow for lower annealing temperatures and/or shorter annealing times because the contact regions 918, 954 have to expand a shorter distance. Additionally or alternatively, this arrangement allows for the dielectric layer 912 formed over the metal line 906 to be thicker because the protruding bond pad 972 can extend into the window 924 and offset the thicker dielectric layer 912 so that the pre-anneal gap between the contact regions 918 and 854 is approximately the same. The protruding bond pad 972 therefore allows for the dielectric layer 912 to be thicker without requiring that the contact regions 918, 954 to expand a greater distance during the annealing process, therefore allowing the annealing temperature and/or annealing time to be maintained.

In the embodiments shown in FIGS. 2A-9, each of the contact regions are formed from a single opening in the dielectric layer formed over the associated metal lines. In other embodiments, however, the contact region can be formed from multiple openings. FIG. 10 is a schematic cross-sectional view of a bonded structure 1060 having a first element 1000 and a second element 1040 hybrid bonded together, where the contact region 1018 for the first element 1000 is formed from multiple openings 1034 extending through the dielectric layer 1012. During the annealing process, metal from the metal line 1006 can expand through the openings 1034 to contact the contact region 1054 of the second element 1040 to form multiple interconnections at the bond interface 1062. In the illustrated embodiment, the second element 1040 includes the bond pad 1072 formed in the field dielectric 1044 and the contact region 1054 is formed as part of the bond pad 1072. In other embodiments, however, the second element 1040 does not include the bond pad 1072 and the field dielectric 1044. In these embodiments, the dielectric layer 1052 can be formed directly on metal line 1046 and the contact region 1054 is formed as part of the metal line 1046.

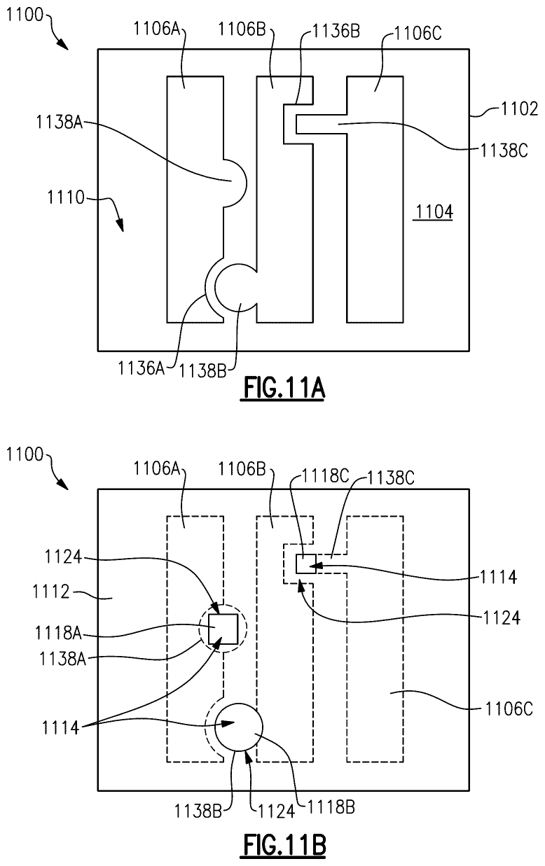

As noted above, in some embodiments, one or more of the metal lines in the metallization layer can have one or more cut outs or extensions to accommodate the layout/structure of another element bonded to the element. FIG. 11A illustrates a top-down plan view of a portion of an element 1100 having metal lines that 1106A-1106C that have cut outs or extensions. The element 1100 comprises a base substrate portion (not shown) and a metallization layer 1102 formed over the base substrate portion. The metallization layer 1102 includes a field dielectric 1104 and the metal lines 1106A-1106C. The metal lines 1106A-1106C extend in a lateral direction along a surface 1110 of the metallization layer 1102. The metal line 1106A has a cut-out portion 1136A and an extension portion 1138A, the metal line 1106B has a cut-out portion 1136B and an extension portion 1138B, and the metal line 1106C has an extension portion 1138C.

The extension portions 1138A-1138C can be positioned such that, when the element 1100 is bonded to a second element, the extension portions 1138A-1138C overlap with and contact the contact regions on the second element. The cut-out portions 1136A, 1136B are formed around the extension portions 1138B, 1138C of adjacent lines to ensure that the extension portions 1138B, 1138C do not overlap with or electrically connect to the adjacent metal line 1106A, 1106B. For example, the extension portion 1138B extends from the metal line 1106B towards the metal line 1106A but the cut-out portion 1136A is positioned and shaped to ensure that the extension portion 1138B does not overlap with or electrically connect to the metal line 1106A, thereby reducing (and even preventing) undesirable crosstalk between the metal lines 1106A and 1106B. Similarly, the extension portion 1138C extends from the metal line 1106C towards the metal line 1106B but the cut-out portion 1136B is positioned and shaped to ensure that the extension portion 1138C does not overlap with or electrically connect to the metal line 1106B, thereby reducing (and even preventing) undesirable crosstalk between the metal lines 1106B and 1106C. However, in some embodiments, one or more of the extension portions can be employed without a corresponding cut-out portion. For example, extension portion 1138A extends from the metal line 1106A towards the adjacent metal line 1106B but does not overlap with the adjacent metal line 1106B. Accordingly, the adjacent metal line 1106B does not include a cut-out portion to accommodate the extension portion 1138A because there is sufficient space between the extension portion 1138A and the metal line 1106B to ensure that the extension portion 1138A and the metal line 1106B do not overlap.

The cut-out portions 1136A, 1136B and the extension portions 1138A-1138C can have any suitable size and shape. In some embodiments, the cut-out portions 1138A-1138C can be rectangular, rounded, hexagonal, or any other suitable regular or irregular shape. In some embodiments, the size and shape of the cut-out portion 1136 can depend on the size and shape of the corresponding extension portion 1138. For example, in the illustrated embodiment, the extension portion 1138B has a circular shape and the corresponding cut-out portion 1136A has curved shape and is sized such that there is sufficient space between the extension portion 1138B and the metal line 1106A. Similarly, the extension portion 1138C has a rectangular shape and the corresponding cut-out portion 1136B also has a rectangular shape and is sized such that the end of the extension portion 1138C does not overlap with the metal line 1106B. In other embodiments, however, the cut-out portion 1136 and the corresponding extension portion 1138 can have different shapes.

As previously discussed, to prevent undesirable crosstalk and substrate coupling between the element 1100 and another element hybrid bonded to the element 1100, a dielectric layer is formed over the metallization layer 1102 that partially covers the metal lines 1106A-1106C. FIG. 11B illustrates a top-down plan view of the element 1100 having a dielectric layer 1112 (which can be as disclosed above with respect to prior embodiments) formed over the metallization layer 1102. The dielectric layer 1112 partially covers the metal lines 1106A-1106C without covering exposed portions 1114 of the metal lines 1106A-1106C. The dielectric layer 1112 has windows 1124 formed therein that are positioned over the metal lines 1106A-1106C to expose the exposed portions 1114 of the metal lines 1106A-1106C. The exposed portions 1114 of the metal lines 1106A-1106C define contact regions 1118A-1118C of the metallization layer 1102 that are configured to facilitate communications between active circuitry within the element 1100 and active circuitry in another element that is hybrid bonded to the element 1100.

In some embodiments, the cut-out portions 1138A-1138C can be rectangular, rounded, hexagonal, or any other suitable regular or irregular shape. In some embodiments, one or more of the contact regions 1118A-1118C can have the same size and shape as the underlying extension portion 1138A-1138C. In these embodiments, the extension portion may not be covered by the dielectric layer 1112 such that the exposed portion 1114 is the entire the extension portion. For example, in the illustrated embodiment, the contact region 1118B is the same size and shape as the underlying extension portion 1138B such that the entire extension portion 1138B is exposed through the dielectric layer 1112. In other embodiments, however, one or more of the contact regions 1118A-1118C can be at least partially covered by the dielectric layer 1112 such that the contact region has a different size and/or shape than the underlying extension portion 1138A-1138C. For example, in the illustrated embodiment, the contact region 1118A has a square shape while the extension portion 1138A has a circular or rounded shape such that the edges of the extension portion 1138 are covered by the dielectric layer 1112. Similarly, the contact region 1118C is formed from the end portion of the extension portion 1138C while the rest of the extension portion 1138C is covered by the dielectric layer. In some embodiments, the size and shape of the contact regions 1118A-1118C can depend on the size and shape of the corresponding contact region on the second element that the element 1100 is to be hybrid bonded to. In general, the contact regions 1118A-1118C can have any suitable size and shape.

### Additional Examples

In accordance with one aspect, a process of forming a microelectronic component is provided. The process includes providing an element having a metallization layer. The metallization layer has a plurality of conductive features extending in a lateral direction along a surface of the metallization layer. The process further includes forming a dielectric layer over the metallization layer, preparing the element for direct bonding, and then exposing a portion of at least one of the plurality of conductive features to define an exposed portion of the at least one of the plurality of conductive features. The exposed portion and the dielectric layer form part of a hybrid bonding surface.

In some embodiments, the dielectric layer has a first thickness, the at least one of the plurality of conductive features has a second thickness, and the first thickness is between about 0.5% and 50% of the second thickness. In some embodiments, the first thickness is between 2 nm and 40 nm. In some embodiments, the second thickness is between 0.1 μm and 5 μm. In some embodiments, the process also includes patterning and etching the metallization layer to form a recessed portion before forming the dielectric layer over the metallization layer, where forming the dielectric layer over the metallization layer includes filling the recessed portion with the dielectric layer. In some embodiments, exposing the portion includes planarizing the dielectric layer to expose a protruding portion of the metallization layer adjacent the recessed portion. In some embodiments, the metallization layer includes a field dielectric material, where the plurality of conductive features are embedded in the field dielectric layer, and the dielectric layer is coplanar with the field dielectric layer. In some embodiments, exposing the portion includes patterning a window in the dielectric layer, where the exposed portion is coplanar with portions of the metallization layer covered by the dielectric layer. In some embodiments, preparing the element for hybrid bonding includes planarizing the dielectric layer sufficiently for hybrid bonding before exposing the portion activating a surface of the dielectric layer after exposing the portion. In some embodiments, the element includes a first element and hybrid bonding surface includes a first hybrid bonding surface and the process also includes providing a second element having a second hybrid bonding surface that includes a conductive feature and a dielectric field region and hybrid bonding the first element to the second element such that the exposed portion and the conductive feature form a metal-to-metal direct bond with one another and the dielectric layer is directly bonded to the dielectric bonding surface without an intervening adhesive.

In accordance with another aspect, a process of forming a bonded structure is provided. The process includes providing an element having a metallization layer, forming a dielectric layer over the metallization layer, polishing the dielectric layer to form a bonding surface, and opening a window through the dielectric layer. The window exposes a contact region of the metallization layer and the contact region serves as a conductive feature of the element. The process further includes preparing the bonding surface and the contact region for hybrid bonding.

In some embodiments, the element includes a first element, the bonding surface includes a first bonding surface, the conductive feature includes a first conductive feature, and the process also includes providing a second element having a second bonding surface and a second conductive feature exposed at the second bonding surface, and hybrid bonding the first element to the second element such that the first bonding surface direct bonds to the second bonding surface and the first and second conductive features form a metal-to- metal direct bond with one another. In some embodiments, the dielectric layer includes a nitrogen-containing dielectric material. In some embodiments, the nitrogen-containing dielectric material includes one or more of silicon nitride, silicon carbonitride, silicon oxycarbonitride, or silicon oxynitride. In some embodiments, forming the dielectric layer does not comprise forming any metallization structures within the dielectric layer. In some embodiments, the metallization layer includes a back-end-of-line (BEOL) layer of the element. In some embodiments, the metallization layer includes a metal line that extends laterally along the surface and the metal line includes the contact region. In some embodiments, the metal line has a first thickness and the dielectric layer has a second thickness that is less than 50% of the first thickness. In some embodiments, the second thickness is 40 nm or less. In some embodiments, the second thickness is 10 nm or less. In some embodiments, preparing the bonding surface and the contact region for hybrid bonding includes activating the bonding surface with one or more plasmas. In some embodiments, the metallization layer includes patterned metal and a field dielectric material that at least partially surrounds the dielectric region, where the patterned metal includes the contact region and an area of the contact region is less than 50% of an area of the patterned metal.

In accordance with another aspect, a process of forming a bonded structure is provided. The process includes providing an element having a metallization layer, where the metallization layer includes patterned metal and a field dielectric material. The process also includes patterning the metallization layer to form recessed portions in the patterned metal and at least one protruding portion of the patterned metal, depositing one or more dielectric materials over the metallization layer, where depositing the one or more dielectric materials over the metallization layer includes filling the recessed portions with the one or more dielectric materials, planarizing the one or more dielectric materials to expose the at least one protruding portion and form a bonding surface. The at least one protruding portion defines a conductive feature, and the process further includes preparing the bonding surface and the conductive feature for hybrid bonding.

In some embodiments, the element includes a first element, the bonding surface includes a first bonding surface, the conductive feature includes a first conductive feature, and the process further includes providing a second element having a second bonding surface and a second conductive feature exposed at the second bonding surface, hybrid bonding the first element to the second element such that the first bonding surface direct bonds to the second bonding surface and the first and second conductive features form a metal-to-metal direct bond with each other. In some embodiments, the protruding portion protrudes relative to an adjacent one of the recessed portions but is recessed relative to the bonding surface. In some embodiments, depositing the one or more dielectric materials over the surface includes depositing a nitrogen-containing dielectric material onto the recessed portions. In some embodiments, depositing the one or more dielectric materials over the surface includes after depositing the nitrogen-containing dielectric material onto the recessed portions, depositing a second dielectric material over the nitrogen-containing dielectric material. In some embodiments, the nitrogen-containing dielectric material includes silicon nitride, silicon carbonitride, silicon oxycarbonitride, or silicon oxynitride. In some embodiments, the patterned metal is embedded in the field dielectric material, and the bonding surface includes the one or more dielectric materials and the field dielectric material. In some embodiments, the field dielectric material and at least one of the one or more dielectric materials are different materials. In some embodiments, depositing the one or more dielectric materials over the metallization layer includes depositing the one or more dielectric materials over the field dielectric material. In some embodiments, planarizing the one or more dielectric materials includes planarizing the one or more dielectric materials to expose the field dielectric material. In some embodiments, the patterned metal includes a metal line that extends laterally along a surface of the metallization layer and the metal line includes the at least one protruding portion and at least one of the recessed portions.

In another aspect, a microelectronic structure is provided. The microelectronic structure includes an element having a metallization layer and a dielectric layer formed over the metallization layer. The metallization layer has a metal line extending in a lateral direction along a surface of the element. The dielectric layer covers a first portion of the metal line but does not cover a second portion of the metal line. The first portion of the metal line has a first thickness and the dielectric layer has a second thickness, where the second thickness is less than 50% of the first thickness.

In some embodiments, the element includes a first element, the microelectronic component also includes a second element directly bonded to the first element and having a dielectric surface and a conductive feature, where the conductive feature is directly bonded to the second portion of the metal line with a metal-to-metal direct bond and the dielectric field region is directly bonded to the dielectric layer without an intervening adhesive. In some embodiments, the metallization layer includes a back end of line (BEOL) layer. In some embodiments, the second thickness is less than 10% of the first thickness. In some embodiments, the first thickness is between 2 nm and 40 nm. In some embodiments, the second thickness is between 0.1 μm and 5 μm. In some embodiments, the metallization layer includes a field dielectric material and the plurality of metal lines are embedded in the field dielectric material. In some embodiments, the dielectric layer is formed over the field dielectric material. In some embodiments, the dielectric layer completely covers the field dielectric material. In some embodiments, metal line includes a recessed portion and the dielectric layer fills the recessed portion. In some embodiments, an upper surface of the dielectric layer is coplanar with the surface of the element. In some embodiments, an upper surface of the dielectric layer is coplanar with the field dielectric material. In some embodiments, the recessed portion is directly adjacent to the portion of the metal line not covered by the dielectric layer. In some embodiments, the dielectric layer and the portion of the metal line form a hybrid bonding surface. In some embodiments, an upper surface of the metal line is coplanar with the portion of the metal line.

In accordance with another aspect, a microelectronic structure is provided. The microelectronic structure includes an element having a metallization layer and a dielectric layer formed over the metallization layer. The metallization layer has a metal line extending in a lateral direction along a surface of the element, and dielectric layer does not cover a portion of the metal line. A thickness of the dielectric layer is 40 nm or less.

In some embodiments, the element includes a first element, the microelectronic component also includes a second element directly bonded to the first element and having a dielectric field region and a conductive feature, the conductive feature is directly bonded to the portion of the metal line with a metal-to-metal direct bond, and the dielectric field region is directly bonded to the dielectric layer without an intervening adhesive. In some embodiments, the thickness of the dielectric layer is 30 nm or less. In some embodiments, the thickness of the dielectric layer is 20 nm or less.

In accordance with another aspect, a bonded structure is provided. The bonded structure includes a first element and a second element directly bonded to the first element. The first element includes a metallization layer and a dielectric layer formed over the metallization layer. The metallization layer has a metal line extending in a lateral direction along a surface of the element the dielectric layer covers a first portion of the metal line but does not cover a second portion of the metal line. The first portion of the metal line has a first thickness and the dielectric layer has a second thickness, where the second thickness is less than 50% of the first thickness. The second element has a dielectric surface and a conductive feature, where the conductive feature is directly bonded to the second portion of the metal line with a metal-to-metal direct bond and the dielectric field region is directly bonded to the dielectric layer without an intervening adhesive.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1-33. (canceled)

34. A microelectronic structure, comprising:
an element having a metallization layer having a metal line extending in a lateral direction along a surface of the element; and
a dielectric layer formed over the metallization layer, wherein the dielectric layer covers a first portion of the metal line but does not cover a second portion of the metal line, wherein the first portion of the metal line has a first thickness and the dielectric layer has a second thickness, and wherein the second thickness is less than 50% of the first thickness.

35. The microelectronic structure of claim 34, wherein the element comprises a first element, the microelectronic component further comprising:
a second element directly bonded to the first element and having a dielectric surface and a conductive feature, wherein the conductive feature is directly bonded to the second portion of the metal line with a metal-to-metal direct bond and wherein the dielectric field region is directly bonded to the dielectric layer without an intervening adhesive.

36. The microelectronic structure of claim 34, wherein the metallization layer comprises a back end of line (BEOL) layer.

37. The microelectronic structure of claim 34, wherein the second thickness is less than 10% of the first thickness.

38. The microelectronic structure of claim 34, wherein the first thickness is between 2 nm and 40 nm.

39. The microelectronic structure of claim 34, wherein the second thickness is between 0.1 μm and 5 μm.

40. The microelectronic structure of claim 34, wherein the metallization layer comprises a field dielectric material and wherein the plurality of metal lines are embedded in the field dielectric material.

41. The microelectronic structure of claim 40, wherein the dielectric layer is formed over the field dielectric material.

42. The microelectronic structure of claim 41, wherein the dielectric layer completely covers the field dielectric material.

43. The microelectronic structure of claim 40, wherein metal line comprises a recessed portion and wherein the dielectric layer fills the recessed portion.

44. The microelectronic structure of claim 43, wherein an upper surface of the dielectric layer is coplanar with the surface of the element.

45. The microelectronic structure of claim 43, wherein an upper surface of the dielectric layer is coplanar with the field dielectric material.

46. The microelectronic structure of claim 43, wherein the recessed portion is directly adjacent to the portion of the metal line not covered by the dielectric layer.

47. The microelectronic structure of claim 34, wherein the dielectric layer and the portion of the metal line form a hybrid bonding surface.

48. The microelectronic structure of claim 34, wherein an upper surface of the metal line is coplanar with the portion of the metal line.

49. A microelectronic structure, comprising:
an element having a metallization layer having a metal line extending in a lateral direction along a surface of the element; and
a dielectric layer formed over the metallization layer, wherein the dielectric layer does not cover a portion of the metal line, wherein a thickness of the dielectric layer is 40 nm or less.

50. The microelectronic structure of claim 49, wherein the element comprises a first element, the microelectronic component further comprising:
a second element directly bonded to the first element and having a dielectric field region and a conductive feature, wherein the conductive feature is directly bonded to the portion of the metal line with a metal-to-metal direct bond and wherein the dielectric field region is directly bonded to the dielectric layer without an intervening adhesive.

51. The microelectronic structure of claim 49, wherein the thickness of the dielectric layer is 30 nm or less.

52. The microelectronic structure of claim 51, wherein the thickness of the dielectric layer is 20 nm or less.

53. A bonded structure, comprising:
a first element, wherein the first element comprises:
a metallization layer having a metal line extending in a lateral direction along a surface of the element; and
a dielectric layer formed over the metallization layer, wherein the dielectric layer covers a first portion of the metal line but does not cover a second portion of the metal line, wherein the first portion of the metal line has a first thickness and the dielectric layer has a second thickness, and wherein the second thickness is less than 50% of the first thickness; and
a second element directly bonded to the first element and having a dielectric surface and a conductive feature, wherein the conductive feature is directly bonded to the second portion of the metal line with a metal-to-metal direct bond and wherein the dielectric field region is directly bonded to the dielectric layer without an intervening adhesive.
